(19) United States
(12) Patent Application Publication
(10) Pub. No.: US 2025/0160008 A1
(43) Pub. Date: May 15, 2025

(54) GE-BASED SHORT WAVELENGTH INFRARED SENSOR, METHOD OF MANUFACTURING THE SAME, AND ELECTRONIC APPARATUS INCLUDING GE-BASED SHORT WAVELENGTH INFRARED SENSOR

(71) Applicant: Samsung Electronics Co., Ltd., Suwon-si (KR)

(72) Inventors: Youngzoon YOON, Suwon-si (KR); Chanwook Baik, Suwon-si (KR); Kyungsang Cho, Suwon-si (KR)

(73) Assignee: Samsung Electronics Co., Ltd., Suwon-si (KR)

(21) Appl. No.: 18/818,187

(22) Filed: Aug. 28, 2024

(30) Foreign Application Priority Data
Nov. 14, 2023 (KR) 10-2023-0157700

(51) Int. Cl. H01L 27/146; G01J 1/44; G01J 5/10

(52) U.S. Cl. CPC H10F 39/8033; G01J 1/44; G01J 5/10; H10F 39/011; H10F 39/184; H10F 39/805; H10F 39/8063

(57) ABSTRACT

A germanium-based short wavelength infrared sensor, a method of manufacturing the same, and an electronic apparatus including the germanium-based short wavelength infrared sensor are provided. The short wavelength infrared sensor according to an example embodiment includes a light absorption layer provided on the substrate layer and having a higher absorption rate for a short wavelength infrared light than an absorption rate for a visible light; a light absorption enhancement layer provided on the light absorption layer to enhance a light absorption rate of the light absorption layer, the light absorption enhancement layer including a plurality of nanostructures; and an upper insulating layer covering the plurality of nanostructures and having a refractive index greater than a refractive index of each of the plurality of nanostructures, wherein the light absorption layer includes germanium (Ge).

### CROSS-REFERENCE TO RELATED APPLICATION

This application is based on and claims priority under 35 U.S.C. § 119 to Korean Patent Application No. 10-2023-0157700, filed on Nov. 14, 2023, in the Korean Intellectual Property Office, the disclosure of which is incorporated by reference herein in its entirety.

### BACKGROUND

### 1. Field

Example embodiments of the disclosure relate to an infrared sensor, and more particularly, to a germanium (Ge)-based short wavelength infrared sensor, a method of manufacturing the same, and an electronic apparatus including a Ge-based short wavelength infrared sensor.

### 2. Description of the Related Art

A short wavelength infrared (SWIR) band has a lower scattering characteristic than near-infrared (NIR) band, thus may observe farther and deeper, and has optical characteristics that are safer for humans.

Smart devices that continuously detect their surroundings and interact with a user have been introduced, and as Internet of Things (IoT) sensors have developed, a demand for SWIR sensors is also increasing.

In view of a maximum permissible exposure (MPE) that may be tolerated by human eyes, the permissible exposure of a SWIR band is relatively high compared to other light bands. Therefore, a relatively strong SWIR light source may be used in an SWIR sensor.

In high-efficiency SWIR sensors, InGaAs is mainly used as a light-absorbing material, but SWIR sensors that use germanium (Ge) or quantum dots (QDs) as a light-absorbing material also have been introduced.

### SUMMARY

One or more example embodiments may provide a short wavelength infrared sensor that increases the absorption rate of short wavelength infrared (SWIR).

Further one or more embodiments may provide a short wavelength infrared sensor that may reduce noise.

Further one or more embodiments may provide a short wavelength infrared sensor that may increase an operating speed.

One or more embodiments may provide a method of manufacturing the short wavelength infrared sensor.

Still further, one or more embodiments may provide an infrared image sensor including the short wavelength infrared sensor.

Still further, one or more embodiments may provide an electronic apparatus including the short wavelength infrared sensor or the infrared image sensor.

Additional aspects will be set forth in part in the description which follows and, in part, will be apparent from the description, or may be learned by practice of the presented embodiments of the disclosure.

According to an aspect of an example embodiment of the disclosure, a short wavelength infrared sensor includes a substrate layer; a light absorption layer provided on the substrate layer and having a higher absorption rate for a short wavelength infrared light than an absorption rate for a visible light; a light absorption enhancement layer provided on the light absorption layer to enhance a light absorption rate of the light absorption layer, the light absorption enhancement layer including a plurality of nanostructures; and an upper insulating layer covering the plurality of nanostructures and having a refractive index greater than a refractive index of each of the plurality of nanostructures, wherein the light absorption layer includes germanium (Ge).

In one example, the substrate layer may include a channel layer, and the channel layer may be in contact with the light absorption layer. The substrate layer may include a p-type substrate, an n+ back gate substrate, and a gate insulating layer. In one example, the light absorption layer may face the n+ back gate substrate with the channel layer therebetween, and the plurality of nanostructures may be in contact with the light absorption layer.

In one example, the short wave infrared sensor may further include a first electrode layer and a second electrode layer that are separated from the light absorption layer, in contact with the channel layer, and spaced apart from each other. The channel layer may include a first type conductive impurity, and the first and second electrode layers may include a region in which the channel layer is doped with a second type conductive impurity. The short wavelength infrared sensor may further include a first contact prevention layer that prevents a contact between the light absorption layer and the first electrode layer, and a second contact prevention layer that prevents a contact between the light absorption layer and the second electrode layer. The light absorption layer may include a first light absorption layer and a second light absorption layer spaced apart from each other between the first contact prevention layer and the second contact prevention layer. In one example, among the plurality of nanostructures, nanostructures provided on the first light absorption layer and nanostructures provided on the second light absorption layer may be provided to be perpendicular to each other.

In one example, the light absorption layer may be provided in a straight-line shape or a curved shape. The plurality of nanostructures may include a metal meta-pattern or a meta-pattern of a dielectric material having a less refractive index than the upper insulating layer. In one example, the light absorption layer may be provided in a cross shape or a zigzag shape.

In one example, among the plurality of nanostructures, a plurality of first nanostructures may be aligned to correspond to a first polarization component of incident light, and a plurality of second nanostructures may be aligned to correspond to a second polarization component of the incident light.

In one example, the plurality of nanostructures may be aligned at a first pitch in a first section of the light absorption layer, and may be aligned at a second pitch different from the first pitch in a second section of the light absorption layer, the second section being different from the first section.

In one example, the light absorption enhancement layer may be provided between the light absorption layer and the substrate layer, and a barrier layer may further be provided between the light absorption layer and the light absorption enhancement layer. In one example, both the light absorption enhancement layer and the barrier layer may be disposed on or below the light absorption layer. In one example, both the light absorption enhancement layer and the barrier layer may be disposed on or above the light absorption layer. A transparent electrode layer may be provided around the plurality of nanostructures on the barrier layer, wherein a height of the transparent electrode layer may be less than that of each of the plurality of nanostructures.

In one example, the light absorption enhancement layer may be provided between the light absorption layer and the substrate layer, and the plurality of nanostructures may be in contact with the light absorption layer.

In one example, an anti-reflection film, a visible light blocking filter, and a micro lens may further be provided above the light absorption layer. In one example, both the light absorption enhancement layer and the barrier layer may be provided below the anti-reflection film, the visible light blocking filter, and the micro lens. A readout circuit layer may be provided above or below the light absorption layer.

According to another aspect of an example embodiment of the disclosure, an infrared image sensor includes a plurality of pixels forming an array, and each of the plurality of pixels includes a short wavelength infrared sensor according to an embodiment.

According to another aspect of an example embodiment of the disclosure, an electronic apparatus includes the short wavelength infrared sensor described above.

According to another aspect of an example embodiment of the disclosure, a method of manufacturing a short wavelength infrared sensor, including forming a light absorption layer having a higher absorption rate for a short wavelength infrared light than an absorption rate for a visible light on a substrate layer, on a substrate layer; forming a plurality of metal nanostructures on the light absorption layer to enhance a light absorption rate of the light absorption layer, and forming an insulating layer covering the plurality of metal nanostructures. The light absorption layer may include germanium (Ge), and the insulating layer may have a refractive index greater than a refractive index of each of the plurality of metal nanostructures.

In one example, the method may further include forming a barrier layer between the light absorption layer and the plurality of metal nanostructures. In one example, the method may further include forming a transparent electrode layer around the plurality of metal nanostructures on the barrier layer. In one example, the method may further include forming an anti-reflection layer, a visible light blocking filter, and a micro lens on the light absorption layer. In one example, the plurality of metal nanostructures may include a first metal nanostructure corresponding to a first polarization component of incident light and a second metal nanostructure corresponding to a second polarization component of the incident light.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

The above and other aspects, features, and advantages of certain embodiments of the disclosure will be more apparent from the following description taken in conjunction with the accompanying drawings, in which:

FIG. 1 is a cross-sectional view of a first infrared sensor according to an example embodiment;

FIG. 2 is a cross-sectional view of a second infrared sensor according to an example embodiment;

FIG. 3 is a perspective view showing a first sample used as a first infrared sensor in a first simulation performed to confirm optical characteristics (e.g., infrared absorption characteristics) of a first infrared sensor according to an example embodiment;

FIG. 4 shows results of a three-dimensional mapping for a light absorption rate according to a pitch of a nanostructure in the first sample of FIG. 3;

FIG. 5 illustrates graphs showing a relationship between a light absorption rate and a wavelength of a region showing a maximum light absorption rate in FIG. 4;

FIG. 6 illustrates graphs showing a relationship between a light absorption rate and a wavelength according to a presence or an absence of a nanostructure and a material of the nanostructure in the first sample of FIG. 3;

FIG. 7 is an image showing a magnetic field distribution that appears in a light absorption layer when the nanostructure of the first sample of FIG. 3 is a metal nanostructure and infrared rays with a wavelength of 1310 nm are incident on the first sample;

FIG. 8 is an image showing an electric field distribution that appears between nanostructures when the nanostructure of the first sample of FIG. 3 is a metal nanostructure and infrared rays with a wavelength of 1310 nm are incident on the first sample;

FIG. 9 is an image showing a Poynting vector distribution map when the nanostructure of the first sample of FIG. 3 is a metal nanostructure and infrared rays with a wavelength of 1310 nm are incident on the first sample;

FIG. 10 illustrates graphs showing a relationship between a light absorption rate and a wavelength according to a presence or an absence of a metal nanostructure and an upper insulating layer (e.g., a SiO₂ layer) on the metal nanostructure in the first sample of FIG. 3;

FIG. 11 illustrates graphs showing an absorption rate difference according to a thickness of the light absorption layer and a relationship between a light absorption rate and a wavelength according to a presence or an absence of a nanostructure in the first sample of FIG. 3;

FIG. 12 illustrates graphs showing a relationship between a light absorption rate and a wavelength according to a material of the nanostructure in the first sample of FIG. 3;

FIGS. 13A, 13B, 14, and 15 are plan views showing various planar arrangements of a light absorption layer provided in a first infrared sensor according to an example embodiment;

FIG. 16 is a plan view showing a case in which nanostructures are not disposed in some sections of the light absorption layer in the planar arrangement illustrated in FIG. 14;

FIG. 17 is a plan view showing a case in which nanostructures are not disposed in some sections of the light absorption layer in the planar arrangement illustrated in FIG. 15;

FIGS. 18 to 22 are cross-sectional views of first to fifth photodiode (PD) samples of a front side illumination (FSI)-type PD sensor used as a second infrared sensor in a second simulation performed to confirm optical characteristics (e.g., infrared absorption characteristics) of a second infrared sensor according to an example embodiment.

FIG. 23 illustrates graphs showing a relationship between a light absorption rate and a wavelength when a thickness of the light absorption layer (Ge layer) is 600 nm in the first to fourth PD samples of FIGS. 18 to 21;

FIG. 24 illustrates graphs showing a relationship between light absorption and wavelength when a thickness of the light absorption layer of the fifth PD sample of FIG. 22 is 600 nm;

FIGS. 25A and 25B are images showing a distribution of a magnetic field and an electric field in the fifth PD sample of FIG. 22 when infrared rays with a wavelength of 1310 nm are incident on the fifth PD sample;

FIGS. 26 to 29 are cross-sectional views showing 6th to 9th PD samples of a back side illumination (BSI) PD type used as a second infrared sensor in a third simulation performed to confirm optical characteristics (e.g., infrared absorption characteristics) of the second infrared sensor according to an example embodiment;

FIG. 30 illustrates graphs showing a relationship between a light absorption rate and a wavelength for the 6th to 9th PD samples of FIGS. 26 to 29;

FIGS. 31A and 31B are images showing an electric field distribution in the 8th and 9th PD samples including a nanostructure when a wavelength of incident light is 1310 nm in the third simulation;

FIG. 32 illustrates graphs showing a relationship between light absorption and wavelength when a thickness of a light absorption layer is 600 nm in the 9th PD sample of FIG. 29;

FIGS. 33A and 33B are images showing a distribution of a magnetic field (a) and an electric field (b) when a thickness of a light absorption layer is 600 nm and infrared rays with a wavelength of 1310 nm are incident to the 9th PD sample of FIG. 29;

FIG. 34 is a plan view of an infrared image sensor according to an example embodiment.

FIGS. 35 to 41 are cross-sectional views showing step by step a method of manufacturing a PD-type infrared sensor according to an example embodiment; and

FIG. 42 is a block diagram showing a schematic configuration of an electronic apparatus according to an example embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, a germanium-based short wavelength infrared sensor, a manufacturing method thereof, and an electronic apparatus including the germanium-based short wavelength infrared sensor according to an example embodiment will be described in detail with reference to the attached drawings. In this process, thicknesses of layers or regions shown in the drawings may be somewhat exaggerated for clarity of the specification.

The embodiments of the disclosure are capable of various modifications and may be embodied in many different forms. In a layer structure described below, when a position of an element is described using an expression “above”, “below” or “on”, the position of the element may include not only the element being “immediately in a contact manner” but also being in a non-contact manner”. In the description below, like reference numerals in the drawings refer to like elements throughout,

The singular forms include the plural forms unless the context clearly indicates otherwise. When a portion “includes” a constituent element, another element may be further included, rather than excluding the existence of the other element, unless otherwise described.

The term “above” and similar directional terms may be applied to both singular and plural. With respect to operations that constitute a method, the operations may be performed in any appropriate sequence unless the sequence of operations is clearly described or unless the context clearly indicates otherwise. The operations may not necessarily be performed in the order of sequence.

Also, in the specification, the terms “units” or “ . . . modules” denote units or modules that process at least one function or operation, and may be realized by hardware, software, or a combination of hardware and software.

Connections or connection members of lines between components shown in the drawings illustrate functional connections and/or physical or circuit connections, and the connections or connection members may be represented by replaceable or additional various functional connections, physical connections, or circuit connections in an actual apparatus.

All examples or example terms are simply used to explain in detail the technical scope of the disclosure, and thus, the scope of the disclosure is not limited by the examples or the example terms as long as it is not defined by the claims.

First, a germanium-based short wavelength infrared sensor according to an example embodiment will be described.

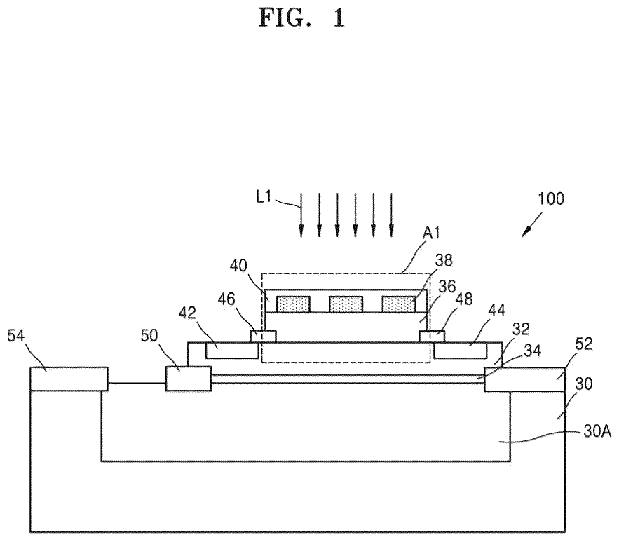

FIG. 1 shows a first infrared sensor 100 according to an example embodiment. The first infrared sensor 100 may be an infrared sensor configured to receive infrared rays in a short wavelength infrared (SWIR) band, but may not be limited thereto.

Referring to FIG. 1, the first infrared sensor 100 may include a substrate 30. In one example, the substrate 30 may be a p-type substrate doped with a p-type impurity, but is not limited thereto. In one example, the substrate 30 may include a silicon substrate. A first doped layer 30A exists in the substrate 30. The first doped layer 30A may also be referred to as a first doped region. The first doped layer 30A may be a region having a given depth downward from an upper surface of the substrate 30. The first doped layer 30A may be a region doped with an n-type impurity. In one example, a doping concentration of the first doped layer 30A may be greater than a doping concentration of the substrate 30 around the first doped layer 30A. In one example, the first doped layer 30A may be an n+ region and may function as a back gate. Therefore, the first doped layer 30A may be expressed as a back gate layer. Due to the presence of the first doped layer 30A, the flow of a dark current corresponding to noise in a channel layer 36 may be controlled. For example, by applying a control voltage to the first doped layer 30A, the dark current or light current flowing in the channel layer 36 may be controlled.

An upper surface of the first doped layer 30A may be a part of the upper surface of the substrate 30. A gate insulating layer 34 may be disposed on the upper surface of the first doped layer 30A, and an n-type channel layer 32 may be provided on the gate insulating layer 34. A first insulating layer 50 and a second insulating layer 52 may be spaced apart from each other on the first doped layer 30A. The gate insulating layer 34 may be provided between the first insulating layer 50 and the second insulating layer 52. The first insulating layer 50 may be in direct contact with the gate insulating layer 34 and also may be in contact with the channel layer 32. The channel layer 32 may cover an entire upper surface of the gate insulating layer 34 and may be in direct contact with the gate insulating layer 34. A portion of the channel layer 32 may extend onto the first insulating layer 50. Due to the first and second insulating layers 50 and 52, the channel layer 32 provided on the gate insulating layer 34 may not contact the first doped layer 30A.

The second insulating layer 52 may be provided on a boundary between the substrate 30 and the first doped layer 30A to cover a portion (or a partial region) of the substrate 30 and the first doped layer 30A. The second insulating layer 52 may be in direct contact with the partial region.

A third insulating layer 54 may be provided on the upper surface of the substrate 30. The third insulating layer 54 may be disposed to face the second insulating layer 52. The first insulating layer 50 may be located between the second insulating layer 52 and the third insulating layer 54. The third insulating layer 54 may be spaced apart from the first insulating layer 50. The third insulating layer 54 may extend onto a portion of the upper surface of the first doped layer 30A.

The gate insulating layer 34 and the first to third insulating layers 50, 52, and 54 may include the same insulating material or dielectric material, but are not limited thereto. In one example, the gate insulating layer 34 and the first to third insulating layers 50, 52, and 54 may be or include silicon oxide (e.g., SiO₂).

In one example, the channel layer 32 may be a material layer through which light current may flow and may include a material layer doped with an n-type impurity. In one example, the channel layer 32 may include an n-type semiconductor layer (e.g., a silicon layer).

A second doped layer 42 and a third doped layer 44 may be formed in the channel layer 32 and spaced apart from each other. The second doped layer 42 may be provided on a first side of the channel layer 32, and the third doped layer 44 may be provided on a second side of the channel layer 32 to face the second doped layer 42. In one example, the second and third doped layers 42 and 44 may be regions doped with p-type impurities. In one example, the second and third doped layers 42 and 44 may have a greater doping concentration than other regions of the channel layer 32. For example, the second and third doped layers 42 and 44 may be p++ substrate layers (e.g., silicon layers). In one example, the second and third doped layers 42 and 44 may be regions to which a voltage is applied during an operation of the first infrared sensor 100 and may be electrode layers. In one example, a gap between the second doped layer 42 and the third doped layer 44 may be 1 μm or less, for example, 500 nm or less, or may be in a range from about 300 nm to about 400 nm, but is not limited to these examples.

A light absorption layer 36 may be provided on the channel layer 32 between the second doped layer 42 and the third doped layer 44. The light absorption layer 36 may be disposed to entirely cover the channel layer 32 between the second and third doped layers 42 and 44 and may be in contact with the channel layer 32. A fourth insulating layer 46 may be provided between the light absorption layer 36 and the second doped layer 42, and a fifth insulating layer 48 may be provided between the light absorption layer 36 and the third doped layer 44. The fourth and fifth insulating layers 46 and 48 may be contact prevention layers that prevent the light absorption layer 36 from directly contacting the second and third doped layers 42 and 44. In one example, the fourth and fifth insulating layers 46 and 48 may include an oxide layer or a nitride layer. In one example, the fourth and fifth insulating layers 46 and 48 may include silicon nitride (e.g., Si₃N₄).

In one example, the light absorption layer 36 may include a photoelectric conversion layer that absorbs infrared rays in the SWIR band and generates photoelectric current through a photoelectric effect. The light absorption layer 36 may have a higher absorption rate for a short wavelength infrared light than an absorption rate for a visible light. In one example, the light absorption layer 36 may be or include a germanium (Ge) layer. A thickness of the light absorption layer 36 may be in a range from about 100 nm to about 2000 nm, in a range from about 200 nm to about 1000 nm, in a range from about 300 nm to about 900 nm, or in a range from about 500 nm to 700 nm, but is not limited thereto.

A plurality of meta-patterns 38 spaced apart from each other may be provided on the light absorption layer 36. The plurality of meta-patterns 38 may be a plurality of nanostructures forming a meta-surface. Heights of the plurality of meta-patterns 38 may all be the same or substantially the same. The plurality of nanostructures may have specifications (e.g., width, height, diameter, etc.) that generate a plasmonic effect or plasmonic amplification effect for incident SWIR and/or the plurality of nanostructures may be arranged to exhibit such effect. The specification(s) of each of the plurality of meta-patterns 38 may correspond to less than half of a wavelength of incident light L1, but are not limited thereto. For example, the width, height, diameter, pitch, etc. of the plurality of meta-patterns 38 may correspond to less than ½ of the SWIR band.

As the plurality of meta-patterns 38 are provided in this way, the incident light L1 may be focused on the meta-patterns 38 and transmitted to the light absorption layer 36. As a result, the light absorption rate of the light absorption layer 36 may be increased compared to when the plurality of nanostructures 38 are not provided. In this sense, the plurality of meta-patterns 38, which are nanostructures, may be expressed as a light absorption reinforcement layer or a light absorption enhancement layer. As the plurality of meta-patterns (or nanostructures) 38 are provided, the light absorption rate of the light absorption layer 36 may increase, and thus, the thickness and/or width of the light absorption layer 36 may be reduced compared to a light absorption layer of an existing infrared sensor that does not include the plurality of nanostructures 38. Here, the width of the light absorption layer 36 refers to the width of the light absorption layer 36 between the second doped layer 42 and the third doped layer 44, which are electrode layers. A decrease in the width of the light absorption layer 36 between the second and third doped layers 42 and 44 may denote a decrease in the channel length, and the decrease in the channel length may denote an increase in an operating speed.

In one example, the plurality of meta-patterns 38 may include a metallic material or a dielectric material. As an example, the plurality of meta-patterns 38 may include at least one of gold (Au), silver (Ag), aluminum (Al), silicon (Si), and titanium nitride (TiN), but are not limited thereto.

The plurality of meta-patterns 38 may be covered with an upper insulating layer 40. The upper insulating layer 40 may be provided to completely cover all the plurality of meta-patterns 38. In one example, the upper insulating layer 40 may include a material having a refractive index greater than that of the plurality of meta-patterns 38. As an example, the upper insulating layer 40 may include silicon oxide (e.g., SiO₂).

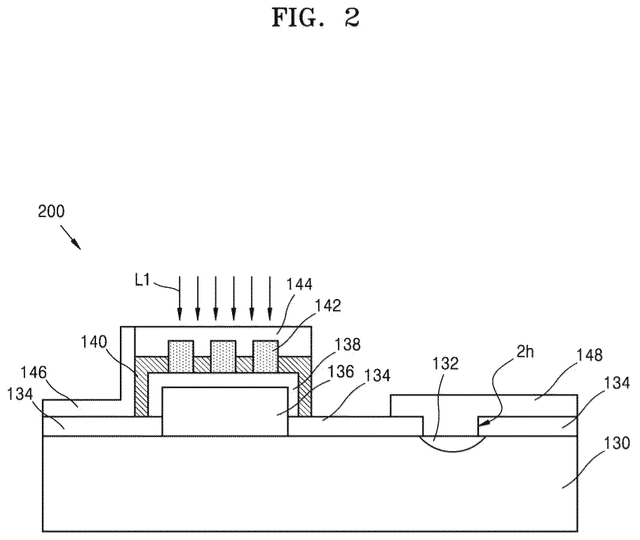

FIG. 2 shows a second infrared sensor 200 according to an example embodiment.

Referring to FIG. 2, the second infrared sensor 200 may include a substrate 130 and a light absorption layer 136, a barrier layer 138, and a plurality of nanostructures 142 sequentially stacked on the substrate 130. In one example, the substrate 130 may be an n-type silicon substrate, but is not limited thereto. A material of the light absorption layer 136 may be the same as the material of the light absorption layer 36 of the first infrared sensor 100, but is not limited thereto. The light absorption layer 136 may be formed on a partial region of the substrate 130. On the substrate 130, a periphery of the light absorption layer 136 may be covered with an insulating layer 134. The insulating layer 134 may cover an upper surface of the substrate 130 and may be in direct contact with the upper surface of the substrate 130. The insulating layer 134 may include silicon oxide (e.g., SiO₂). The insulating layer 134 may include a via hole 2h at a position spaced apart from the light absorption layer 136. The substrate 130 may be exposed through the via hole 2h, and a first doped layer 132 may be provided on the substrate 130 exposed through the via hole 2h. The first doped layer 132 may be spaced apart from a lower surface of the substrate 130. The first doped layer 132 may be spaced apart from the light absorption layer 136. A diameter of an upper surface of the first doped layer 132 may be greater than a diameter of the via hole 2h. Therefore, only a portion of the first doped layer 132 may be exposed through the via hole 2h. In one example, the first doped layer 132 may be a region doped with an n-type impurity at a greater concentration than the substrate 130. In one example, the first doped layer 132 may be an n++ doped region.

The barrier layer 138 provided on the light absorption layer 136 may be a layer for preventing or minimizing flow of a dark current, which is noise, and may include, for example, titanium oxide (TiO₂), but is not limited thereto.

The barrier layer 138 may be provided to cover both an upper surface and a side surface of the light absorption layer 136. Accordingly, the plurality of nanostructures 142 provided on the barrier layer 138 do not contact the light absorption layer 136. Additionally, the plurality of nanostructures 142 may be a meta-pattern, and a material and specification characteristics thereof may be the same as those of the plurality of nanostructures 38 of FIG. 1.

Because the nanostructure 142 is provided, when light L1 is incident on the nanostructure 142, the light L1 may be focused on the nanostructure 142 and may reach the absorption layer 136 by passing through the barrier layer 138. That is, photons of the incident light L1 may be trapped in the light absorption layer 136 by the nanostructure 142, and as a result, the light absorption rate of the light absorption layer 136 may increase. The barrier layer 138 may be formed to have a thickness that allows such light trapping to occur in the light absorption layer 136.

A transparent conductive oxide layer 140, which is an electrode layer, may be provided between the plurality of nanostructures 142. The transparent conductive oxide layer 140 may have a thickness less than that of each of the plurality of nanostructures 142 and a height less than that of each of the plurality of nanostructures 142. The transparent conductive oxide layer 140 may cover all side surfaces of the barrier layer 138 and may also cover an entire upper surface of the barrier layer 138 between the plurality of nanostructures 142. That is, the entire surface of the barrier layer 138 around the plurality of nanostructures 142 may be covered with the transparent conductive oxide layer 140. In one example, the transparent conductive oxide layer 140 may include an indium tin oxide (ITO) layer. An upper insulating layer 144 covering the plurality of nanostructures 142 may be provided on the transparent conductive oxide layer 140. An upper surface of the upper insulating layer 144 may be flat. The upper insulating layer 144 may include a material layer having a greater refractive index than that of the plurality of nanostructures 142. In one example, the upper insulating layer 144 may include silicon oxide (e.g., SiO₂), but is not limited thereto. Because the upper insulating layer 144 having the structure described above is provided, the light reflectance in the plurality of nanostructures 142 may be lowered and photon trapping by the nanostructure 142 may be increased in the light absorption layer 136.

A first electrode layer 146 may be provided on the insulating layer 134 on a left side of the light absorption layer 136. The first electrode layer 146 may be provided to cover a side surface of the transparent conductive oxide layer 140, and a bottom of the first electrode layer 146 may be in contact with the insulating layer 134. The first electrode layer 146 may also cover a side surface of the upper insulating layer 144 that contacts and extends from the side surface of the transparent conductive oxide layer 140. The first electrode layer 146 may be in direct contact with the transparent conductive oxide layer 140. The first electrode layer 146 may be formed as a single layer or a multiple layers. For example, the first electrode layer 146 may include a TiN layer and a Mo layer sequentially stacked, but is not limited thereto.

A second electrode layer 148 may be formed on the insulating layer 134 in contact with the via hole 2h. The second electrode layer 148 may be separated from the transparent conductive oxide layer 140 and fill the via hole 2h. The second electrode layer 148 may be in direct contact with the first doped layer 132 exposed through the via hole 2h. The layer structure and material of the second electrode layer 148 may be the same as those of the first electrode layer 146.

Next, a first simulation performed to confirm optical characteristics (e.g., infrared absorption characteristics) of the first infrared sensor 100 according to an example embodiment and its results are described.

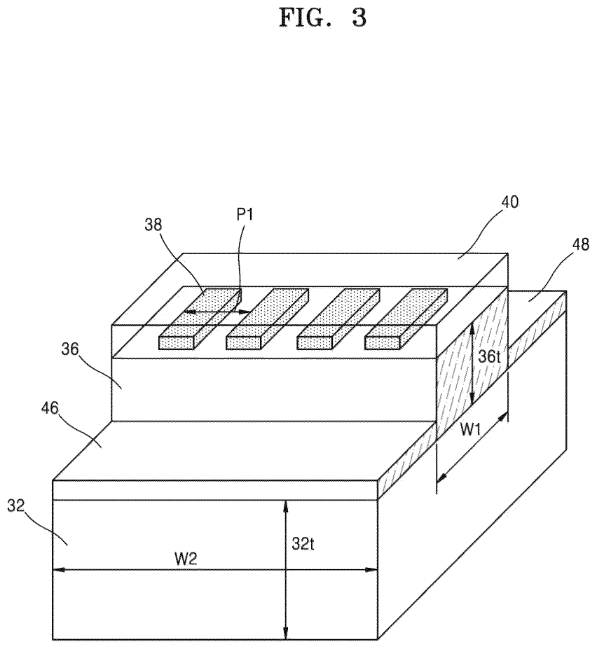

FIG. 3 shows a first sample used as the first infrared sensor 100 in the first simulation. For convenience, the first sample may be set to include only a portion corresponding to a first region A1 of the first infrared sensor 100 of FIG. 1.

In the first simulation, the channel layer 32 of the first sample was set to a silicon layer, the fourth and fifth insulating layers 46 and 48 were set to silicon nitride layers (Si₂Nx), the light absorption layer 36 was set to a Ge layer, and the nanostructure 38 was set to a metal nanograting including Ag.

Additionally, a thickness 32t of the channel layer 32 was set to 20 μm (20,000 nm) and a width (W2) was set to 3,000 nm. A width W1 of the light absorption layer 36 between the fourth and fifth insulating layers 46 and 48 was set to 1 micrometer (μm) or less, for example, 500 nm. A thickness 36t of the light absorption layer 36 was set to 600 nm. A width and a thickness (or height) of each nanostructure 38 were set to 200 nm, and a gap between the plurality of nanostructures 38 was set to 150 nm. The plurality of nanostructures 38 were arranged at a pitch P1 of 350 nm on the light absorption layer 36 along a length of the light absorption layer 36. The upper insulating layer 40 covering the plurality of nanostructures 38 was set as a SiO₂ layer with a thickness of 250 nm. In the first simulation, these settings were adjusted as needed.

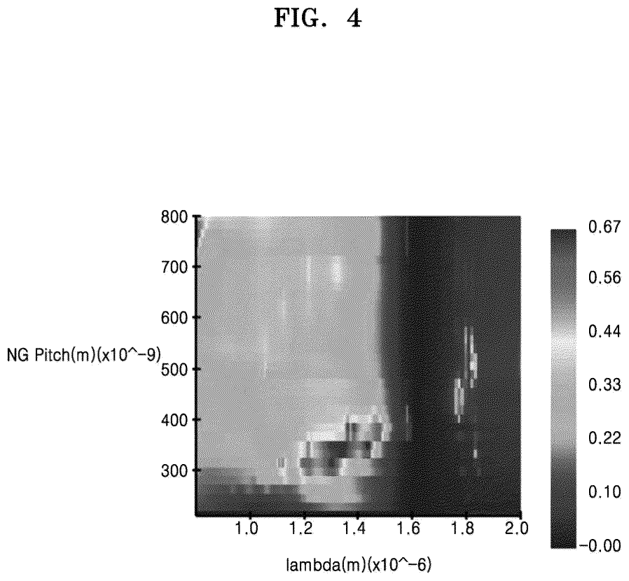

FIGS. 4 to 12 show results of the first simulation.

FIG. 4 shows a three-dimensional mapping of a relationship between a pitch of the nanostructure 38, the wavelength of incident light, and light absorption rate in the first sample of FIG. 3.

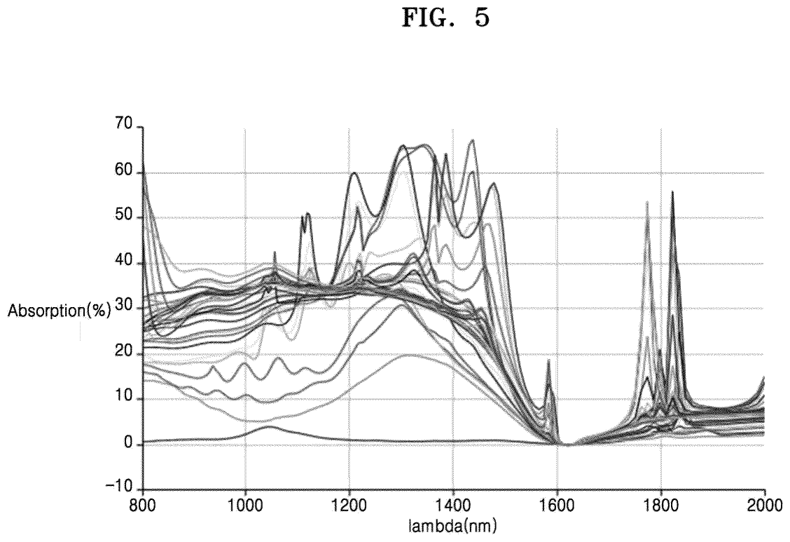

Referring to FIG. 4, the maximum light absorption efficiency is shown when the pitch of the nanostructure 38 is about 350 nm. FIG. 5 shows a relationship between a light absorption rate and a wavelength in a region where the maximum light absorption efficiency is shown in FIG. 4.

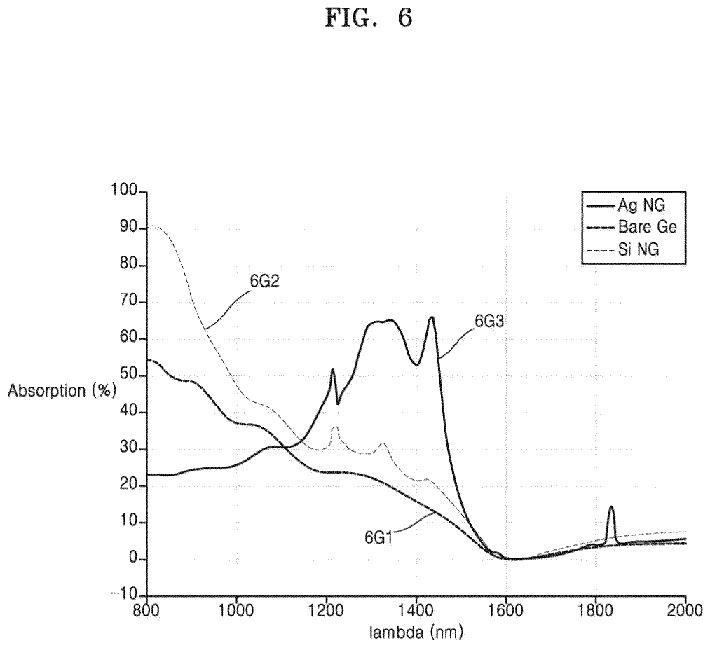

FIG. 6 shows a relationship between a light absorption rate and a wavelength when a width and a height of the nanostructures 38 in the first sample are each 200 nm, and the pitch of the nanostructures 38 arranged in the nanograting is 350 nm.

In FIG. 6, a first graph 6G1 shows the relationship between a light absorption rate and a wavelength when the first sample includes a Ge light absorption layer as the light absorption layer 36 and does not include the nanostructure 38. A second graph 6G2 shows the relationship between a light absorption rate and a wavelength when the nanostructure 38 in the first sample is a silicon Si nanograting. A third graph 6G3 shows the relationship between a light absorption rate and a wavelength when the nanostructure 38 in the first sample is a silver Ag nanograting.

Referring to FIG. 6, the light absorption rate increases from the first graph 6G1 to the third graph 6G3 in a wavelength band range from about 1200 nm to about 1500 nm. For example, when a wavelength of incident light is 1310 nm, the light absorption rate is about 21% in the first graph 6G1, 29% in the second graph 6G2, and 65% in the third graph 6G3.

These results show that when the nanostructure 38 is provided on the Ge light absorption layer 36, the light absorption rate increases compared to a case where the nanostructure 38 is not provided, and it shows that the light absorption rate further increases when the material of the nanostructure 38 is a metallic material rather than a dielectric material or a non-metallic material.

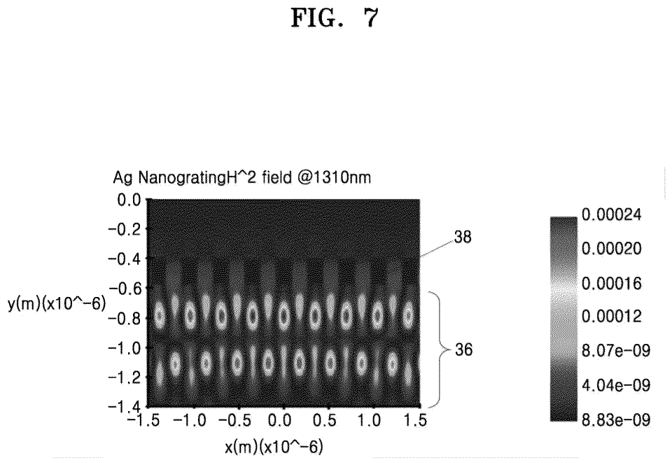

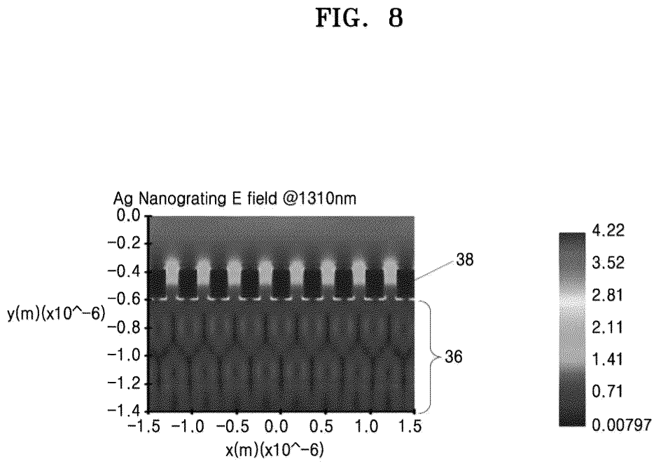

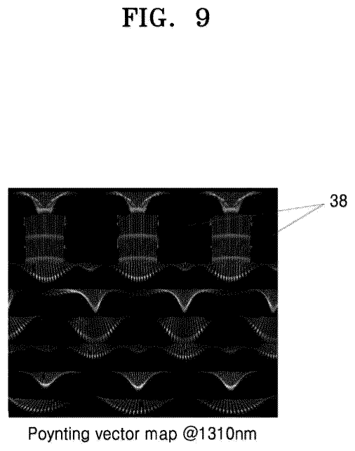

FIG. 7 shows a magnetic field distribution that appears in the light absorption layer 36 when the nanostructure 38 of the first sample of FIG. 3 is a metal nanostructure and infrared rays having a wavelength of 1310 nm are incident on the first sample. FIG. 8 shows an electric field distribution that appears between the nanostructures 38 and FIG. 9 shows a Poynting vector distribution map, when the nanostructure 38 of the first sample of FIG. 3 is a metal nanostructure and infrared rays having a wavelength of 1310 nm are incident on the first sample.

Referring to FIG. 7, it may be seen that a strong magnetic field (H\hat{ }2 field) mode is formed in the Ge light absorption layer 36 with the metal nanostructures 38.

Referring to FIG. 8, the electric field (E field) is trapped between the metal nanostructures 38.

These results in FIGS. 7 and 8 show that the entire photon energy of the incident light is trapped in the Ge light absorption layer 36.

These results may also be confirmed in a distribution map of a Poynting vector in FIG. 9. Referring to FIG. 9, because the photon energy is absorbed between the metal nanostructures 38 and forms a mode in which the photon energy is strongly condensed at the bottom of the metal nanostructures 38, it may be seen that the metal nanostructure 38 increases the light absorption rate of the Ge light absorption layer 36.

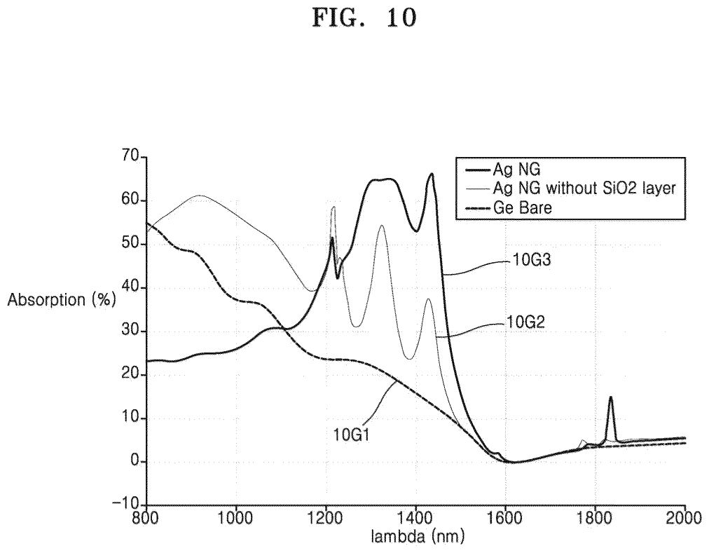

FIG. 10 illustrates graphs showing a relationship between a light absorption rate and a wavelength when a thickness of the light absorption layer 36 of the first sample of FIG. 3 is 600 nm, according to whether the first sample includes or not include the upper insulating layer 40 covering the nanostructures 38.

A first graph 10G1 in FIG. 10 shows the relationship between a light absorption rate and a wavelength when the first sample does not include the nanostructures 38 and the upper insulating layer 40. A second graph 10G2 shows the relationship between a light absorption rate and a wavelength when the first sample includes the nanostructures 38 but does not include the upper insulating layer 40. A third graph 10G3 shows the relationship between a light absorption rate and a wavelength when the first sample includes both the nanostructures 38 and the upper insulating layer 40.

Comparing the first to third graphs 10G1 to 10G3 of FIG. 10, in a wavelength band range from about 1200 nm to about 1500 nm, a light absorption rate when the first sample includes the nanostructure 38 is higher than a light absorption rate when the first sample does not include the nanostructure 38, and when the first sample includes the nanostructure 38, the light absorption rate when the upper insulating layer 40 covering the nanostructure 38 is provided is higher than the light absorption rate when the upper insulating layer 40 is not provided. For example, when a wavelength of light incident on the first sample is 1310 nm, which belongs to the SWIR band, in the case of the first graph 10G1, the light absorption rate is about 21%, in the case of the second graph 10G2, the light absorption rate is about 47%, and in the case of the third graph 10G3, the light absorption rate is about 65%, which is higher than those of the first and second graphs 10G1 and 10G2.

The results of FIG. 10 show that the light absorption rate when the first sample includes the upper insulating layer 40 covering the nanostructure 38 is higher than the light absorption rate when the first sample does not include the upper insulating layer 40 covering the nanostructure 38.

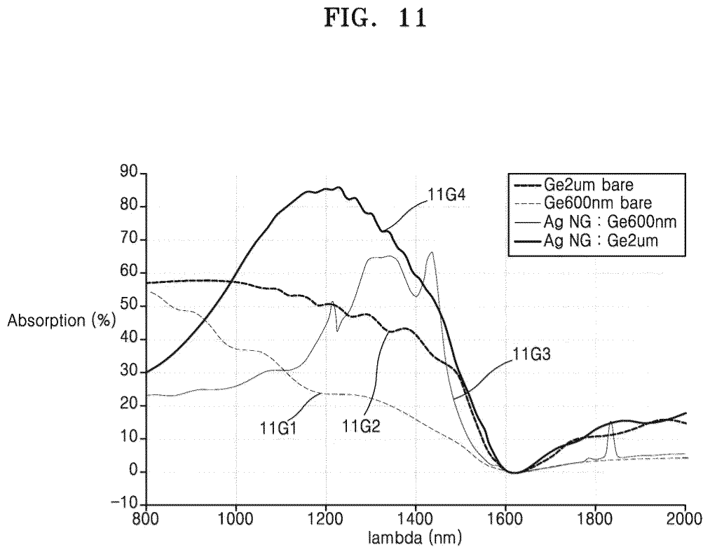

FIG. 11 illustrates graphs showing a relationship between a light absorption rate and a wavelength according to a thickness of the light absorption layer 36 of the first sample of FIG. 3.

In FIG. 11, first and second graphs 11G1 and 11G2 correspond to a case where the first sample does not include the nanostructure 38, wherein the first graph 11G1 corresponds to a case where the thickness of the light absorption layer 36 is 600 nm and the second graph 11G2 corresponds to a case where the thickness of the light absorption layer 36 is 2 μm. Third and fourth graphs 11G3 and 11G4 correspond to a case where the first sample includes the nanostructure 38, wherein the third graph 11G3 corresponds to a case where the thickness of the light absorption layer 36 is 600 nm and the fourth graph 11G4 corresponds to a case where the thickness of the light absorption layer 36 is 2 μm.

Comparing the first to fourth graphs 11G1 to 11G4 of FIG. 11, the third and fourth graphs 11G3 and 11G4 are located at a higher position (that is, higher absorption) than the first and second graphs 11G1 and 11G2 at a wavelength range of about 1250 nm to about 1400 nm. These results may denote that regardless of the thickness of the light absorption layer 36, when the first sample includes the nanostructure 38, the light absorption rate in the wavelength band range of at least 1250 nm to 1400 nm is higher than the light absorption rate when the first sample does not include the nanostructure 38.

The first and second graphs 11G1 and 11G2 of FIG. 11 show that the light absorption rate increases as the thickness of the light absorption layer 36 increases under the condition that the first sample does not include the nanostructure 38. The third and fourth graphs 11G3 and 11G4 show that under the condition that the first sample includes the nanostructure 38, as the thickness of the light absorption layer 36 increases, the light absorption rate increases except for some wavelength bands (e.g., greater than about 1400 nm and less than about 1500 nm).

As a result, the light absorption rate in the wavelength band range from about 1250 nm to about 1400 nm increases from the first graph 11G1 to the fourth graph 11G4. For example, when the wavelength of incident light is 1310 nm, the light absorption rate is about 21% in the first graph 11G1, the light absorption rate is about 46% in the second graph 11G2, the light absorption rate is about 65% in the third graph 11G3 is about 65%, and the light absorption rate is about 76% in the fourth graph 11G4.

The results of FIG. 11 along with other simulation results described above may be used for a structural design of the first infrared sensor 100. For example, if a thickness of a light absorption layer of an existing infrared sensor that receives SWIR is about 2 μm, the result of FIG. 11 may suggest a structure in which the nanostructure 38 is disposed on the light absorption layer 36 of the first infrared sensor 100 while keeping the thickness of the light absorption layer 36 less than 2 μm (e.g., reducing the thickness of the light absorption layer 36 to about 600 nm). In addition, if a thickness of a light absorption layer of an existing infrared sensor is about 600 nm, the results of FIG. 11 may suggest a structure in which the nanostructure 38 is disposed on the light absorption layer 36 while making the thickness of the light absorption layer 36 of the first infrared sensor 100 less than 600 nm.

The results of FIG. 11 may also suggest a case that the thickness and/or width of the light absorption layer 36 may be reduced compared to the light absorption layer of an existing infrared sensor while maintaining the light absorption rate of the first infrared sensor 100 equivalent to that of the existing infrared sensor. If a width of the light absorption layer 36 between the second and third doped layers 42 and 44, which are electrode layers, is reduced, a channel length between the second and third doped layers 42 and 44 may be reduced, thereby increasing the operating speed. Therefore, the results of FIG. 11 may suggest that the operation speed of the first infrared sensor 100 may be greater than that of the existing infrared sensor while maintaining the light absorption rate of the first infrared sensor 100 equivalent to that of the existing infrared sensor.

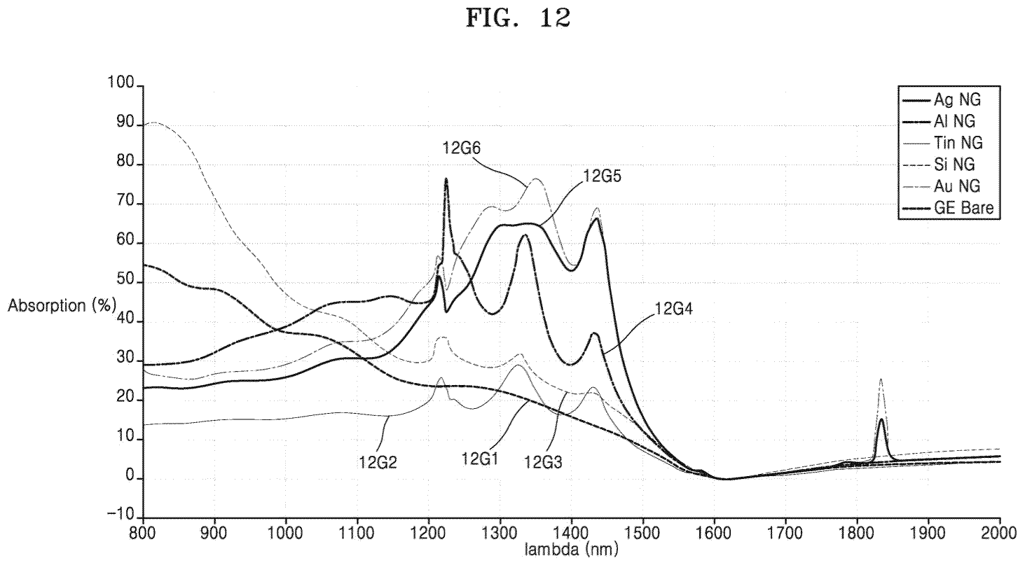

FIG. 12 illustrate graphs showing a relationship between a light absorption rate and a wavelength according to a material of the nanostructure 38, that is, a type of material when the thickness of the light absorption layer 36 of the first sample of FIG. 3 is 600 nm.

A first graph 12G1 in FIG. 12 shows a case where the first sample does not include the nanostructure 38. Second to sixth graphs 12G2 to 12G6 show when materials of the nanostructure 38 of the first sample are TiN, Si, Al, Ag, and Au, respectively. Here, silicon (Si) may be an intrinsic semiconductor Si that is not doped with an impurity.

Comparing the first to sixth graphs 12G1 to 12G6 of FIG. 12, when the nanostructure 38 is present, regardless of the material of the nanostructure 38, the light absorption rate increases compared to a case where the nanostructure 38 is not present, in at least a wavelength band range from about 1200 nm to about 1500 nm. However, if the nanostructure 38 is a TiN nanostructure, the light absorption rate in some wavelength bands (e.g., about 1200 nm-about 1300 nm band) of the above wavelength band range is less than when the nanostructure 38 is not present.

Comparing only the second to sixth graphs 12G2 to 12G6, the light absorption rate is lowest when the material of the nanostructure 38 is TIN and increases in the order of Si, Al, Ag, and Au.

For example, when the wavelength of incident light is 1310 nm, the light absorption rate is about 21% in the first graph 12G1, about 26% in the second graph 12G2, about 29% in the third graph 12G3, about 47% in the fourth graph 12G4, about 65% in the fifth graph 12G5, and about 68% in the sixth graph 12G6.

The results of FIG. 12 suggest that, at a wavelength of 1300 nm or more, if the first sample is provided with the nanostructure 38, the light absorption rate increases compared to when the nanostructure 38 is not provided, regardless of the material of the nanostructure 38, and suggest that, in the case where the nanostructure 38 is provided, the light absorption rate is greater when the material of the nanostructure 38 is a metal (Au, Ag, Al, etc.) than when the material is a dielectric material (e.g., TiN, Si, etc.). If the material of the nanostructure 38 is a metal, the light absorption rate increases in the order of Al, Ag, and Au in the wavelength band range from about 1250 nm to about 1500 nm, which belongs to the SWIR band.

From the first simulation results described above, the light absorption layer 36 and the nanostructure 38 of the first infrared sensor 100 may be designed such that the light absorption rate and the operation speed are increased. For example, the light absorption layer 36 of the first infrared sensor 100 may include a Ge layer with a thickness of 600 nm or less, and the nanostructure 38 may be a nanostructure including Au or Ag or may include such a nanostructure.

The light absorption layer 36 may be provided in various shapes on a plane in the first infrared sensor 100. Because the nanostructures 38 are arranged in a direction in which the light absorption layer 36 extends or in a longitudinal direction of the light absorption layer 36 on the light absorption layer 36, the nanostructures 38 may also have various arrangement forms on a plane.

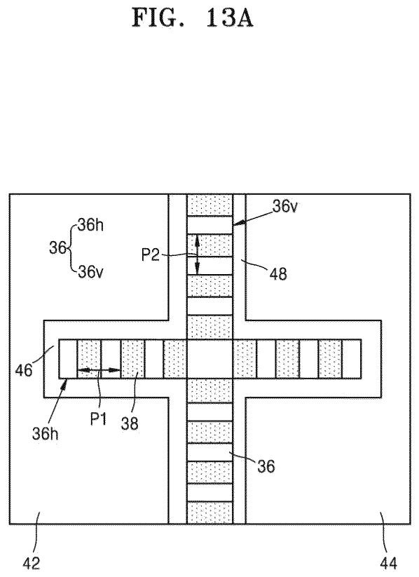

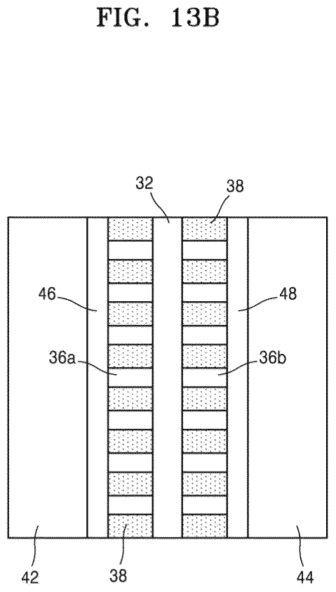

FIGS. 13A to 15 show examples of various arrangement forms of the light absorption layer 36 and the nanostructure 38, but the arrangement forms are not limited to those shown in FIGS. 13A to 15.

FIG. 13A shows a case where the light absorption layer 36 is formed in a cross shape including a horizontal portion 36h and a vertical portion 36v, and the nanostructure 38 is disposed thereon.

Referring to FIG. 13A, some of the plurality of nanostructures 38 may be arranged in a line to have a first pitch P1 along the horizontal portion 36h of the light absorption layer 36, and some of the plurality of nanostructures 38 may be aligned in a row to have a second pitch P2 along the vertical portion 36v. Therefore, an overall arrangement of the plurality of nanostructures 38 may have a shape of a cross. In one example, values of the first and second pitches P1 and P2 may be the same or substantially the same, but are not limited thereto. The size of each of the plurality of nanostructures 38 may be the same or substantially the same, but may also be different.

Incident light may include several polarization components. Considering the polarization of the incident light, the nanostructures 38 provided in the horizontal portion 36h and the nanostructures 38 provided in the vertical portion 36v may be arranged to be perpendicular to each other. In other words, some of the plurality of nanostructures 38 aligned on the light absorption layer 36 may be arranged to correspond to a first polarization component (e.g., vertical polarization) of the incident light, and some of the plurality of nanostructures 38 may be arranged to correspond to or react to a second polarization component (e.g., horizontal polarization) of the incident light.

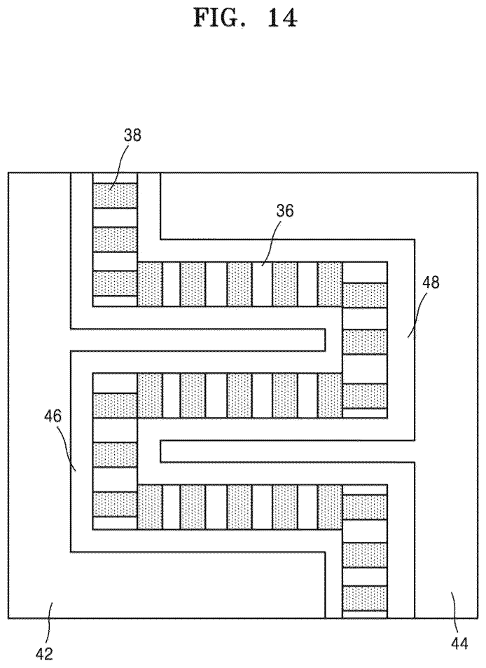

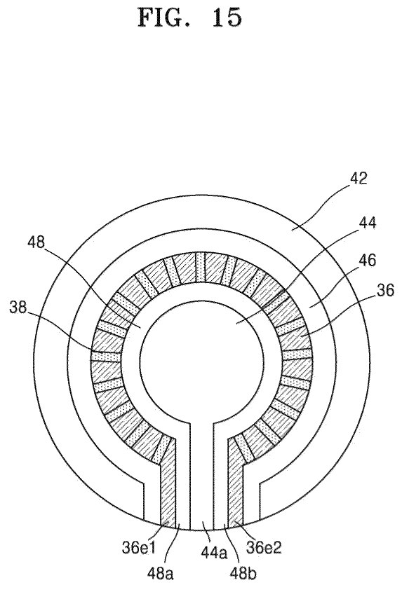

Based on this configuration, the light absorption rate enhancement effect may be exhibited regardless of the polarization state of the incident light. In the case of FIGS. 14 and 15, a plurality of nanostructures 38 may be arranged considering the polarization state of incident light.

In one example, a width of each of the plurality of nanostructures 38 disposed on the horizontal portion 36h of the light absorption layer 36 may be the same or substantially the same, or widths of some of the plurality of nanostructures 38 may be different from those of the other plurality of nanostructures 38. In one example, a width of each of the plurality of nanostructures 38 disposed on the vertical portion 36v in the vertical direction may be the same or substantially the same, or a width of some of the plurality of nanostructures 38 may be different from that of the other plurality of nanostructures 38.

In one example, the nanostructure 38 disposed on the vertical portion 36v of the light absorption layer 36 may be the same as the nanostructure 38 disposed 90° clockwise or counterclockwise on the horizontal portion 36h of the light absorption layer 36.

If the arrangement of the plurality of nanostructures 38 in FIG. 13A is explained differently, it may be expressed that some of the plurality of nanostructures 38 are arranged in a first direction and some of the plurality of nanostructures 38 are arranged in a second direction different from the first direction. The first and second directions may be perpendicular to each other.

In one example, as shown in FIG. 13B, the light absorption layer 36 may be divided into two light absorption layers (e.g., a first light absorption layer 36a and a second light absorption layer 36b) that are spaced apart from each other between the fourth insulating layer 46 and the fifth insulating layer 48. The first light absorption layer 36a and the second light absorption layer 36b may be arranged parallel to each other.

The channel layer 32 between the first and second light absorption layers 36a and 36b may be exposed. The nanostructures 38 formed on the first and second light absorption layers 36a and 36b are illustrated parallel to each other, but considering the polarization of the incident light, the nanostructures 38 disposed on the first light absorption layer 36a and the nanostructures 38 disposed on the second light absorption layer 36b may be arranged perpendicular to each other.

FIG. 14 shows a case where the light absorption layer 36 is formed in a zigzag shape and a plurality of nanostructures 38 are arranged thereon. Accordingly, an overall planar arrangement of the plurality of nanostructures 38 may also have a zigzag shape.

The light absorption layer 36 having a zigzag shape may include a plurality of horizontal portions and a plurality of vertical portions, and the horizontal portions may be arranged alternately with the vertical portions. Regarding the arrangement of the plurality of nanostructures 38 on the horizontal portion and the vertical portion, the descriptions given with reference to FIG. 13A may be applied.

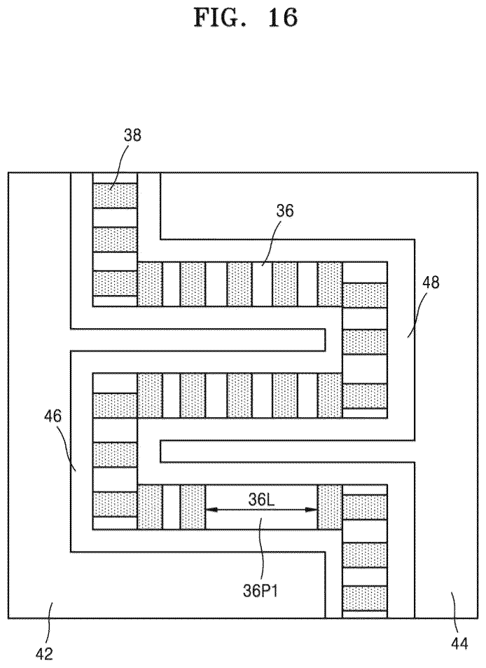

In FIG. 14, the plurality of nanostructures 38 may be arranged at regular intervals or pitches or at substantially constant intervals or pitches over an entire upper surface of the light absorption layer 36, but the plurality of nanostructures 38 may not be arranged on the entire upper surface of the light absorption layer 36 and may be disposed only on a portion of the upper surface of the light absorption layer 36. For example, as shown in FIG. 16, the nanostructures 38 may not be present in a first section 36P1 of the light absorption layer 36. A length 36L of the first section 36P1 in the longitudinal direction of the light absorption layer 36 may be greater than a spacing or pitch of the plurality of nanostructures 38. As an example, the first section 36P1 may be a region where two or more nanostructures 38 may be arranged at the spacing or pitch of the nanostructures 38 arranged in FIG. 14. As an example, the first section 36P1 may be a region from which at least one nanostructure 38 has been removed in the case of FIG. 14. In one example, the length 36L of the first section 36P1 may be less than a length of the horizontal portion or a vertical portion of the light absorption layer 36. In an example embodiment, a second section on which the nanostructures 38 are not provided may be further provided in the case of FIG. 16, wherein the second section is spaced apart from the first section 36P1.

Because the plurality of nanostructures 38 arranged along the length of the light absorption layer 36 on the light absorption layer 36 are spaced apart at a given interval and a given pitch, assuming that the plurality of nanostructures 38 are formed on a first surface (e.g., upper surface) of the light absorption layer 36, the first surface of the light absorption layer 36 may be divided into a plurality of first regions where the nanostructures 38 are present and a plurality of second regions where the nanostructures 38 are not present, and the plurality of second regions may be located between the plurality of first regions. In the case of FIG. 14, a plurality of nanostructures 38 are arranged at substantially the same spacing and pitch, and the size (e.g., width or area) of each of the plurality of second regions may be considered to be substantially the same. However, in the case of FIG. 16, the size of one selected region among the plurality of second regions may be viewed as being greater than the size of the other second regions. The first section 36P1 may be the one selected region.

FIG. 15 shows a case where a planar shape of the light absorption layer 36 is a circular shape and a plurality of nanostructures 38 are arranged on the light absorption layer 36. Accordingly, the planar arrangement shape of the plurality of nanostructures 38 may also have the same circular shape as that of the light absorption layer 36.

Although the planar shape of the light absorption layer 36 is a circular shape, it may be in the form of an open circle rather than a closed circle. For example, one end (start point) and the other end (end point) of the light absorption layer 36 may be at different positions on the channel layer 32, and a portion connecting the one end and the other end of the light absorption layer 36 may be circular. The one end and the other end of the light absorbing layer 36 are spaced apart from each other, and the light absorbing layer 36 may include a first extended portion 36e1 and a second extended portion 36e2, respectively extending outward from the one end and the other end, in parallel with each other.

In FIG. 15, the fourth insulating layer 46 may be formed to be circular on the outside of the light absorption layer 36, the fifth insulating layer 48 may be formed in a circular shape on the inside of the light absorption layer 36, the second doped layer 42 may be formed in a circular shape on the outside of the light absorption layer 36, and the third doped layer 44 may be formed in a circular shape on the inside the light absorption layer 36. In one example, an entire inner region surrounded by the light absorption layer 36, that is, the entire inside of the light absorption layer 36 may be on the third doped layer 44. The fifth insulating layer 48 may be formed between the third doped layer 44 and the light absorbing layer 36 to prevent the light absorbing layer 36 from coming into direct contact the third doped layer 44.

The fifth insulating layer 48 may include extended portions 48a and 48b that start at both ends of the circular portion, are spaced apart from each other, and extend outward. The extended portions 48a and 48b of the fifth insulating layer 48 may be parallel to each other. The extended portions 48a and 48b of the fifth insulating layer 48 may be provided between the first extended portion 36e1 and the second extended portion 36e2 of the light absorption layer 36. The extended portions 48a and 48b of the fifth insulating layer 48 may be disposed parallel to the first extended portion 36e1 and the second extended portion 36e2 of the light absorption layer 36, but may be disposed otherwise.

The third doped layer 44 may include an outwardly extended portion 44a, and the extended portion 44a may extend between the extended portions 48a and 48b of the fifth insulating layer 48.

In one example, in FIG. 15, a width of each nanostructure 38 may vary from the inside to the outside of the circular light absorption layer 36, that is, in a direction in which the radius of the light absorption layer 36 increases. That is, the width of each nanostructure 38 in FIG. 15 may not be constant.

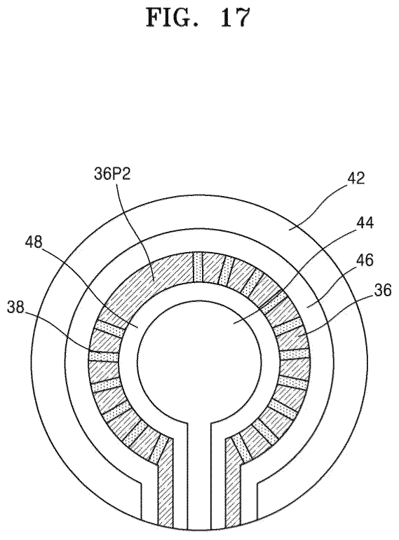

As in the case of FIG. 15, the plurality of nanostructures 38 may be arranged at substantially constant intervals and constant pitches along the light absorption layer 36, but the spacing and pitch of the nanostructures 38 in some regions of the light absorption layer 36 may be different from the remaining regions of the light absorption layer 36. FIG. 17 shows an example of the above case.

Referring to FIG. 17, the nanostructure 38 does not exist in a second section 36P2 of the entire section of the light absorption layer 36 having a circular shape. A length of an arc of the second section 36P2 may be greater than the spacing or pitch between the plurality of nanostructures 38. Accordingly, hypothetically assuming that the nanostructures 38 are disposed in the second section 36P2, one or two or more nanostructures 38 may be disposed. The second section 36P2 may be a region where at least one nanostructure 38 of the plurality of nanostructures 38 disposed on the light absorption layer 36 in FIG. 15 is removed.

Although the light absorption layer 36 is illustrated as circular in FIG. 15, the light absorption layer 36 may also have a non-circular shape (e.g., an oval shape or a curved shape).

Next, a second simulation performed to confirm optical characteristics (e.g., infrared absorption characteristics) of the second infrared sensor 200 of FIG. 2 and its results are described.

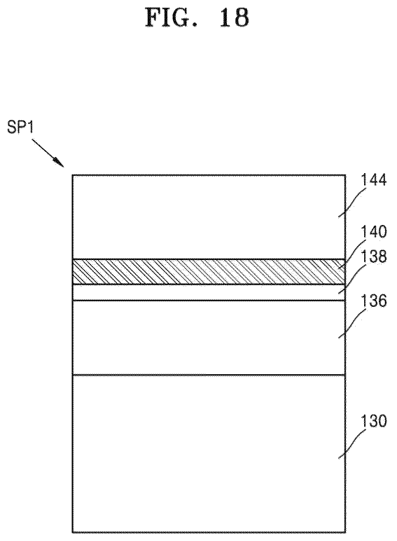

FIGS. 18 to 22 show first to fifth photodiode (PD) samples SP1 to SP5 for infrared sensing used in the second simulation.

The first PD sample SP1 shown in FIG. 18 has no nanostructure on the light absorption layer 136. The first PD sample SP1 may correspond to an infrared sensor of the related art.

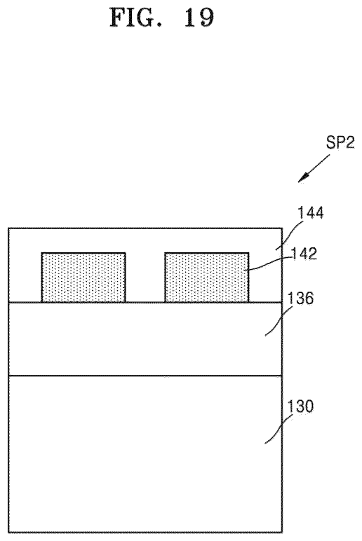

In the case of the second PD sample SP2 shown in FIG. 19, the nanostructure 142 is provided directly on the light absorption layer 136, and the nanostructure 136 is covered with the upper insulating layer 144. That is, the nanostructure 142 is formed directly on the light absorption layer 136, and the barrier layer 138 and/or the transparent electrode layer 140 provided as a barrier to reduce or prevent dark current are not present between the light absorption layer 136 and the nanostructure 142.

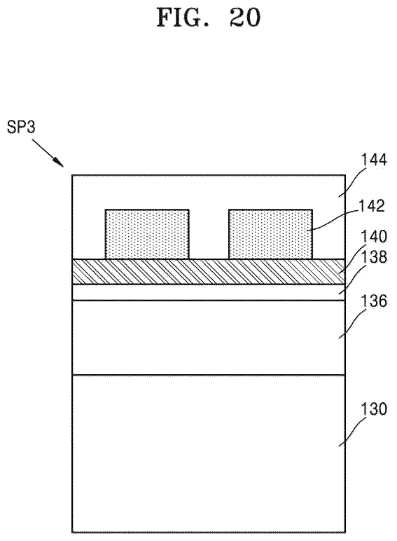

In the case of the third PD sample SP3 shown in FIG. 20, the third PD sample SP3 has a structure in which the light absorption layer 136, the barrier layer 138, the transparent electrode layer 140, the nanostructures 142, and the upper insulating layer 144 are sequentially stacked.

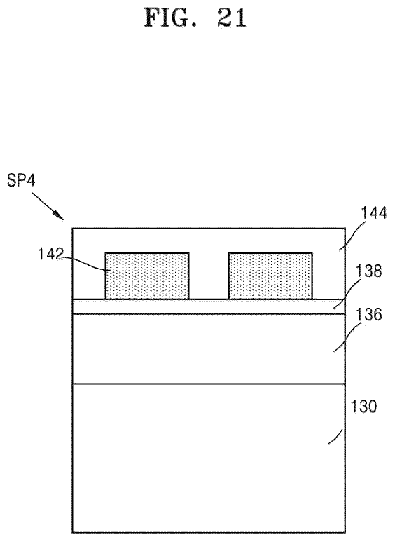

The fourth PD sample SP4 shown in FIG. 21 corresponds to a case where the transparent electrode layer 140 between the barrier layer 138 and the nanostructure 142 of the third PD sample SP3 is removed and the upper insulating layer 144 is provided in a structure entirely surrounding the nanostructure 142.

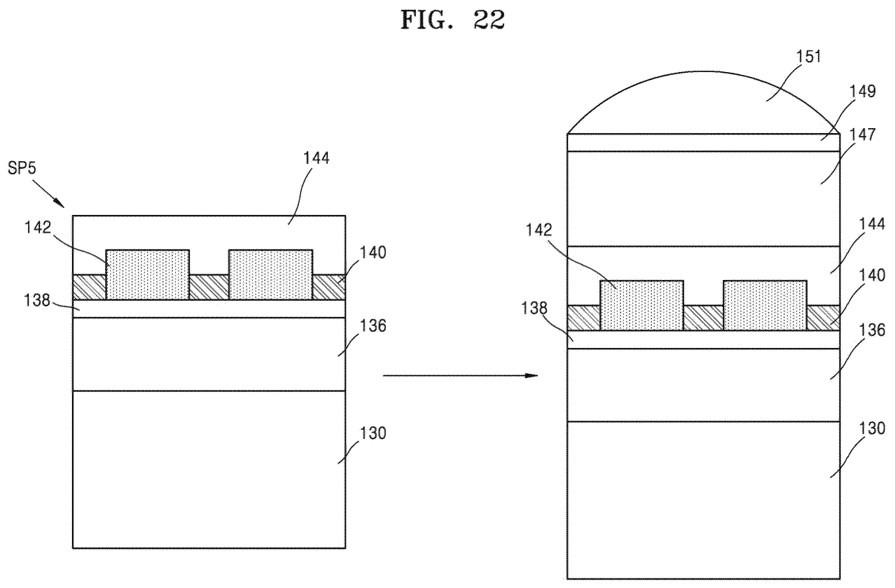

The fifth PD sample SP5 shown in FIG. 22 corresponds to a case where the transparent electrode layer 140 is provided only on the barrier layer 138 between the nanostructures 142 of the third PD sample SP3 and the transparent electrode layer 140 is not provided between the nanostructures 142 and the barrier layer 138. In the fifth PD sample SP5, a thickness of the transparent electrode layer 140 may be less than a thickness of the nanostructures 142, and a height of the transparent electrode layer 140 may be less than a height of the nanostructures 142. As shown on the right, the fifth PD sample SP5 may include a read-out IC (ROIC) layer 147, an anti-reflection layer 149, and a micro lens 151 may be sequentially provided on the upper insulating layer 144. Control of a photo current generated by the light absorption layer 136 and processing of an electrical signal corresponding to the photo current may be performed by the ROIC layer 147. The anti-reflection layer 149 may be a light anti-reflection layer and may be a layer provided to prevent reflection of at least infrared rays. The anti-reflection layer 149 may include a layer structure in which material layers with different refractive indices are sequentially stacked. As an example, the anti-reflection layer 149 may be formed by sequentially stacking a silicon layer and a silicon oxide layer.

The micro lens 151 may be provided to collect incident light into the light absorption layer 136. A filter to block visible light may be provided between the upper insulating layer 144 and the micro lens 151. This filter may be provided on the micro lens 151.

In the second simulation, the substrate 130 of the first to fifth PD samples SP1 to SP5 was set to a 2 μm silicon layer, the light absorption layer 136 was set to a 600 nm Ge layer, and the barrier layer 138 was set to a 10 nm titanium oxide (TiO₂) layer. Also, the transparent electrode layer 140 was set to a 100 nm ITO layer, the nanostructure 142 was set to an Au nanostructure, the thickness of each nanostructure 142 was set to 200 nm and the width was set to 200 nm, a pitch of the nanostructures 142 was set to 350 nm, and the spacing between the nanostructures 142 was set to 150 nm. The upper insulating layer 144 was set to a silicon oxide (SiO₂) layer.

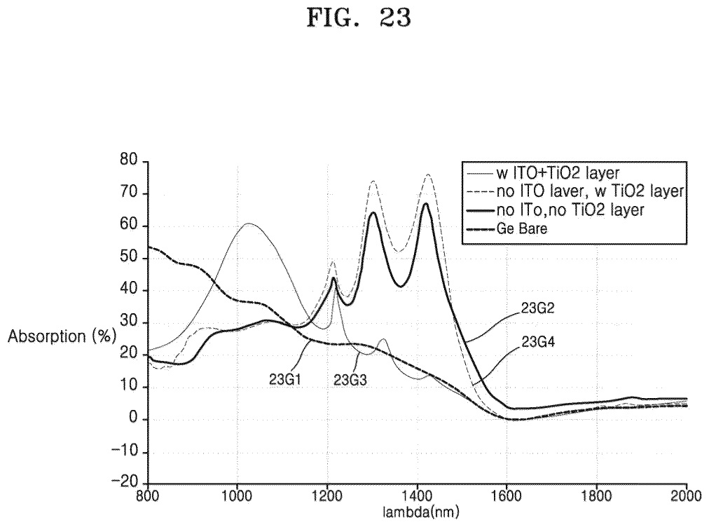

FIGS. 23 to 25 show the results of the second simulation.

FIG. 23 shows the results of light absorption measurement for the first to fourth PD samples SP1 to SP4. In FIG. 23, the horizontal axis represents a wavelength of incident light and the vertical axis represents a light absorption rate.

In FIG. 23, a first graph 23G1 shows a relationship between a light absorption rate and a wavelength for the first PD sample SP1. A second graph 23G2 shows a relationship between a light absorption rate and a wavelength for the second PD sample SP2. A third graph 23G3 shows a relationship between a light absorption rate and a wavelength for the third PD sample SP3. A fourth graph 23G4 shows a relationship between a light absorption rate and a wavelength for the fourth PD sample SP4.

Comparing the first to fourth graphs 23G1 to 23G4, the light absorption rates of the second and fourth PD samples SP2 and SP4 in the infrared band (e.g., 1200 nm to 1500 nm) are greater than those of the first and third PD samples SP1 and SP3. This suggests that the light absorption rate in a case where the transparent electrode layer 140 is not present between the nanostructures 142 and the barrier layer 138, or is not present between the nanostructures 142 while the nanostructures 142 are provided (second graph 23G2 and fourth graph 23G4 for the second and fourth PD sample SP2 and SP4) is greater than a light absorption rate in a case where the nanostructures 142 are not included (first graph 23G1, first PD sample SP1) and in a case where both the barrier layer 138 and the electrode layer 140 are provided between the nanostructures 142 and the light absorption layer 136 (third graph 23G3, third PD sample SP3).

In addition, comparing the second and fourth graphs 23G2 and 23G4, in the infrared band (e.g., 1200 nm to 1500 nm), the light absorption rate in the case where the nanostructures 142 are included without the electrode layer 140 and the barrier layer 138 (second graph 23G2, second PD sample) is less than the light absorption rate at the case where the transparent electrode layer 140 is not provided between and below the nanostructures 142 but only the barrier layer 138 is provided between the nanostructures 142 and the light absorption layer 136 (fourth graph 23G4, fourth PD sample).

As an example, based on the light absorption rate measured at a wavelength of 1310 nm, the light absorption rate of the first PD sample SP1 (first graph 23G1) and the third PD sample SP3 (third graph 23G3) is about 21%, the light absorption rate of the second PD sample SP2 (second graph 23G2) is about 62%, and the light absorption rate of the fourth PD sample SP4 (fourth graph 23G4) is about 72%.

From the results of FIG. 23, it may be seen that as the nanostructures 142 are provided, there is an effect of increasing the light absorption rate and when the nanostructures 142 are disposed directly on the barrier layer 138, the effect may further be increased.

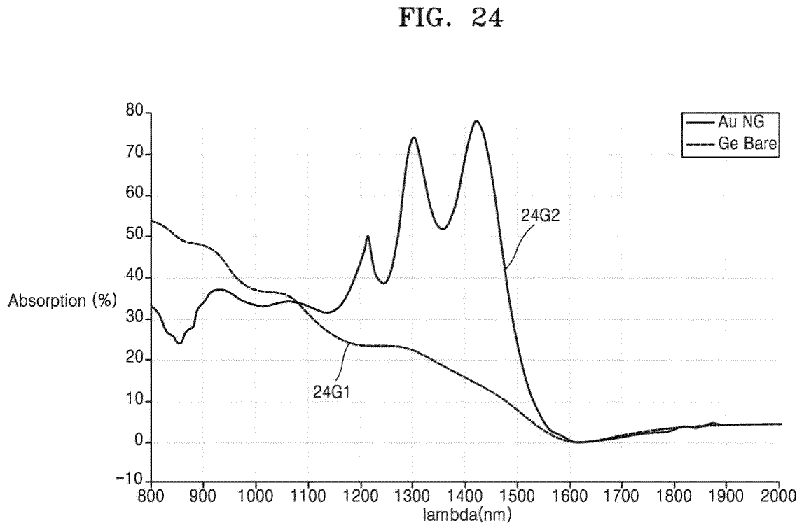

FIG. 24 shows measurement results of light absorption rate for the fifth PD sample SP5. In FIG. 24, the horizontal axis represents a wavelength of incident light and the vertical axis represents a light absorption rate.

In FIG. 24, a first graph 24G1 shows a relationship between a light absorption rate and a wavelength for the first PD sample SP1, and the second graph 24G2 shows a relationship between a light absorption rate and a wavelength for the fifth PD sample SP5.

Comparing the first and second graphs 24G1 and 24G2 in FIG. 24, the light absorption rate of the fifth PD sample SP5 in the infrared band (e.g., 1100 nm to 1600 nm) is much greater than the light absorption rate of the first PD sample SP1. For example, at a wavelength of 1310 nm, the light absorption rate of the first PD sample SP1 is about 21%, while the light absorption rate of the fifth PD sample SP5 is about 72%.

The results suggest that the light absorption rate may be increased by about 3.4 times, compared to the case where the nanostructure 142 is not provided, by disposing the metal nanostructure 142 on the light absorption layer 136, disposing the transparent electrode layer 140 between the metal nanostructures 142, and covering the nanostructure 142 with the upper insulating layer 144 having a refractive index greater than that of the nanostructure 142, as in the fifth PD sample SP5.

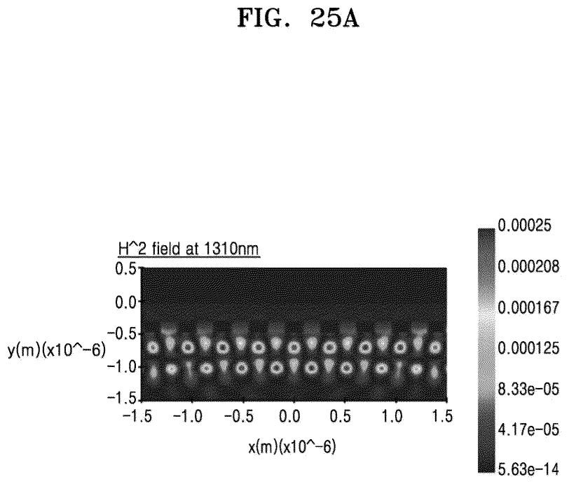

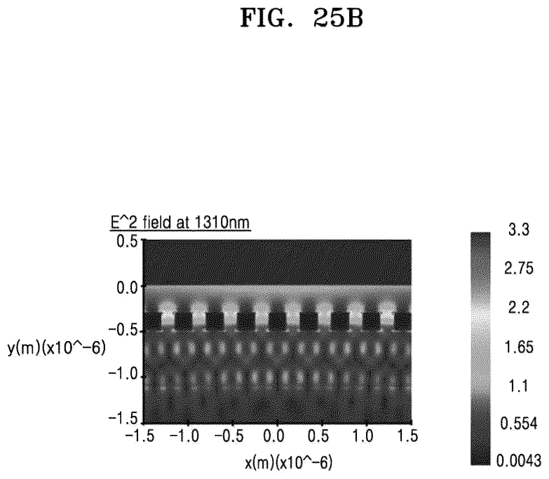

FIG. 25A shows a magnetic field distribution that appears in the light absorption layer 136 when the nanostructure 142 of the fifth PD sample SP5 is an Au nanograting and infrared rays with a wavelength of 1310 nm are incident on the fifth PD sample SP5.

FIG. 25B shows an electric field distribution that appears between the nanostructures 142 in the light absorption layer 136 when the nanostructure 142 of the fifth PD sample SP5 is an Au nanograting and infrared rays with a wavelength of 1310 nm are incident on the fifth PD sample SP5.

Referring to FIG. 25A, it may be seen that a strong magnetic field (H\hat{ }2 field) mode is formed in the light absorption layer 136 under the nanostructures 142.

Referring to FIG. 25B, it may be seen that an electric field (E field) is trapped between the nanostructures 142.

As a result, FIGS. 25A and 25B show that entire photon energy of incident light is trapped in the light absorption layer 136.

Next, a third simulation performed to confirm optical characteristics (e.g., light absorption rate) and its results will be described when the barrier layer 138 and the nanostructures 142 are provided below the light absorption layer in the second infrared sensor 200, that is, when the second infrared sensor 200 is a back side illumination (BSI) type infrared sensor.

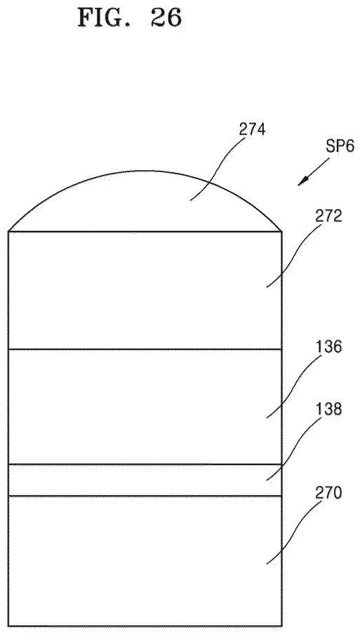

FIGS. 26 to 29 show sixth to ninth PD samples SP6 to SP9 used in the third simulation.

The sixth PD sample SP6 shown in FIG. 26 includes a first silicon layer 270 below the light absorption layer 136, a barrier layer 138 between the light absorption layer 136 and the first silicon layer 270, and a second silicon layer 272 and a micro lens 274 sequentially on the light absorption layer 136. An ROIC layer may be provided instead of the first silicon layer 270, or the ROIC layer may be provided under the first silicon layer 270. The second silicon layer 272 may have been used as a substrate in a process of manufacturing the sixth PD sample SP6. Incident light may enter the light absorption layer 136 through the micro lens 274 and the second silicon layer 272. The second silicon layer 272 may be an example of a material layer that blocks visible light. An additional visible light blocking filter may be provided between the second silicon layer 272 and the micro lens 274.

In the third simulation, a thickness of the first silicon layer 270 was set to 20 μm, a thickness of the barrier layer 138 was set to 10 nm, a thickness of the light absorption layer 136 was set to 2 μm, and a thickness of the second silicon layer 272 was set to 3 μm. A material of the light absorption layer 136 was set to Ge, a material of the barrier layer 138 was set to TiO₂, and a material of the micro lens 274 was set to SiO₂. The thickness and material of each layer were set to be changeable.

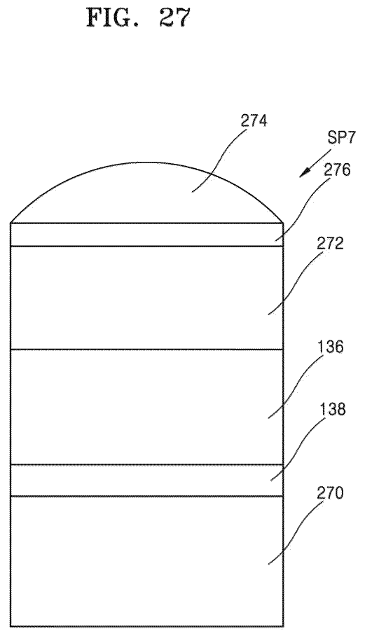

The seventh PD sample SP7 shown in FIG. 27 corresponds to a case where an anti-reflection layer 276 is further provided between the micro lens 274 and the second silicon layer 272 in the sixth PD sample SP6. In the third simulation, the anti-reflection layer 276 was set to have a layer structure in which a SiO₂ layer and a Si layer were sequentially stacked, and a thickness of the SiO₂ layer was set to 88 nm and a thickness of the Si layer was set to 22 nm.

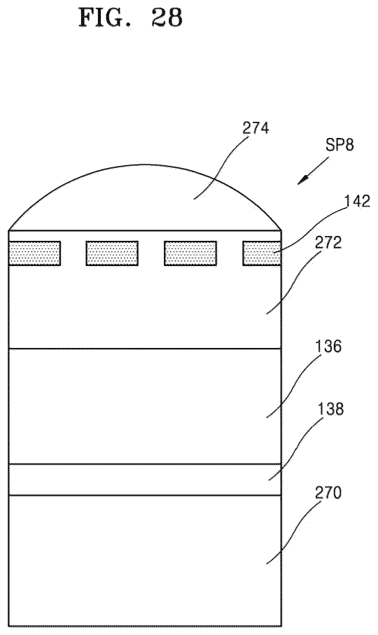

The eighth PD sample SP8 shown in FIG. 28 corresponds to a case where the nanostructures 142 are provided between the second silicon layer 272 and the micro lens 274 in the sixth PD sample SP6. The nanostructures 142 are metal nanostructures and were set to Au nanostructures. The nanostructures 142 were set in the form of nano posts, a diameter of each nanostructure 142 was set to 200 nm, a thickness was set to 88 nm, and a distance between the nanostructures 142 was set to 600 nm.

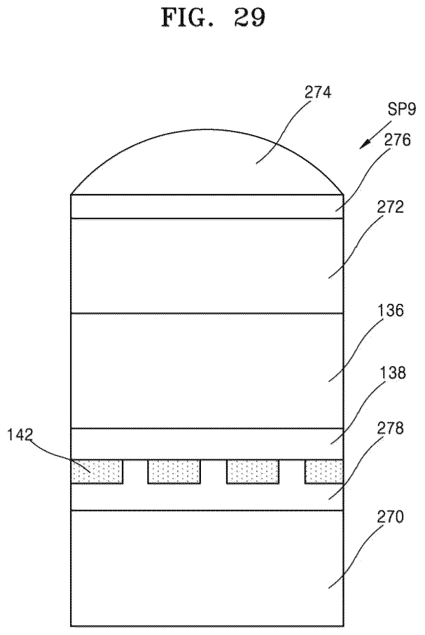

The ninth PD sample SP9 shown in FIG. 29 corresponds to a case where the metal nanostructures 142 are provided between the barrier layer 138 and the first silicon layer 270 in the seventh PD sample SP7. The plurality of nanostructures 142 contact a bottom surface of the barrier layer 138. A lower insulating layer 278 is provided between the nanostructures 142 and the first silicon layer 270. Bottom and side surfaces of the nanostructures 142 are covered with the lower insulating layer 278, and a space between the nanostructures 142 is filled with the lower insulating layer 278. The nanostructures 142 were set in the form of nano posts, a diameter and thickness of each nanostructure 142 were set to 200 nm, and a distance between the nanostructures 142 was set to 600 nm.

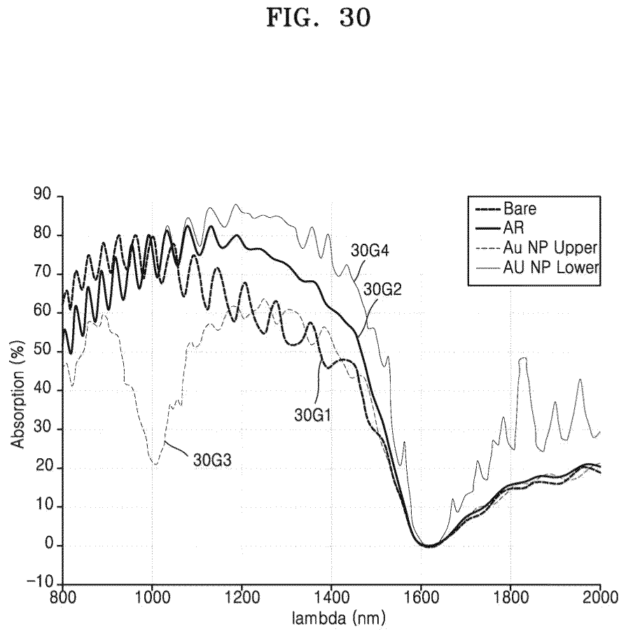

FIGS. 30 to 33 show results of the third simulation.

FIG. 30 shows a relationship between a light absorption rate and a wavelength for the sixth to ninth PD samples SP6 to SP9. The horizontal axis represents wavelength and the vertical axis represents light absorption rate.

In FIG. 30, a first graph 30G1 shows a relationship between a light absorption rate and a wavelength for the sixth PD sample SP6. A second graph 30G2 shows a relationship between a light absorption rate and a wavelength for the seventh PD sample SP7. A third graph 30G3 shows a relationship between a light absorption rate and a wavelength for the eighth PD sample SP8. A fourth graph 30G4 shows a relationship between a light absorption rate and a wavelength for the ninth PD sample SP9.

Comparing the first to fourth graphs 30G1 to 30G4, the light absorption rate in the case where the nanostructures 142 are located above the light absorption layer 136 and are provided between the micro lens 274 and the second silicon layer 272 (eighth PD sample SP8, third graph 30G3) is less than the light absorption rate in the case where the anti-reflection layer 276 is included but the nanostructures 142 are not included (seventh PD sample SP7, second graph 30G2), and is less than the light absorption rate in the case where the anti-reflection layer 276 is included and the nanostructures 142 are provided under the light absorption layer 136 (ninth PD sample SP9, fourth graph 30G4).

In addition, the light absorption rate (fourth graph 30G4) of the ninth PD sample SP9 among the sixth to ninth PD samples SP6 to SP9 in the infrared band (e.g., at least 1100 nm to 2000 nm) is the highest.

For example, in incident light with a wavelength of 1310 nm, the light absorption rate of the sixth PD sample SP6 (first graph 30G1) is about 52%, the light absorption rate of the seventh PD sample SP7 (second graph 30G2) is about 71%, the light absorption rate of the 8th PD sample SP8 (third graph 30G3) is about 61%, and the light absorption rate of the 9th PD sample SP9 (4th graph 30G4) is about 82%.

The results of FIG. 30 suggest that, in the case of a PD-type infrared sensor to which light is incident on a rear side thereof, even if the PD-type infrared sensor includes the metal nanostructure 142, according to the location of the nanostructure 142, the light absorption rate may be less than the case of not including the nanostructure 142 but including the anti-reflection layer 276 and the micro lens 274, and also suggest that the nanostructures 142 may be provided under the light absorption layer 136 to increase the light absorption rate compared to a case where the nanostructures 142 are not included.

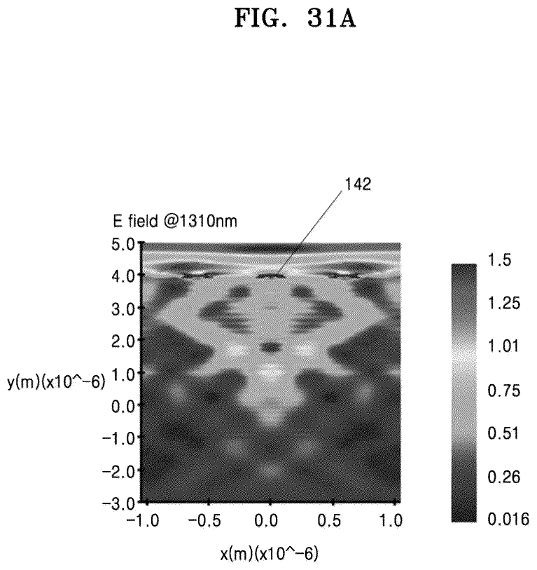

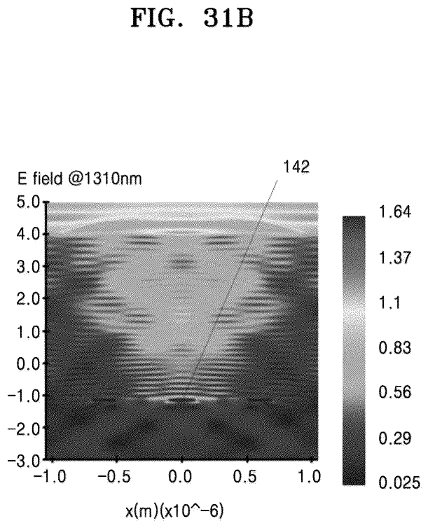

FIGS. 31A and 31B shows an electric field distribution in the 8th and 9th PD samples SP8 and SP9 including the nanostructures 142 among the 6th to 9th PD samples SP6 to SP9 when the wavelength of incident light is 1310 nm.

FIG. 31A corresponds to the 8th PD sample SP8, and FIG. 31B corresponds to the 9th PD sample SP9.

In the case of the eighth PD sample SP8, the nanostructures 142 are not provided directly above the light absorption layer 136, but are provided between the second silicon layer 276 and the micro lens 274, which are sequentially stacked above the light absorption layer 136, and thus, a plasmonic amplification effect caused by the nanostructures 142 may not be transmitted to the light absorption layer 136. Accordingly, the nanostructures 142 of the eighth PD sample SP8 do not significantly contribute to increasing the light absorption rate.

Based on the electric field distribution shown in FIG. 31A, in the case of the eighth PD sample SP8, it may be seen that the electric field is not concentrated on the light absorption layer 136 and mostly stays in the second silicon layer 276.

On the other hand, in the case of the ninth PD sample SP9, the nanostructures 142 are provided below the light absorption layer 136, and thus, the plasmonic amplification effect by the nanostructures 142 may be transmitted to the light absorption layer 136. FIG. 31B shows that the electric field is concentrated on the light absorption layer 136 by the nanostructures 142 provided below the light absorption layer 136, which suggests that the plasmonic amplification effect by the nanostructures 142 is transmitted to the light absorption layer 136.

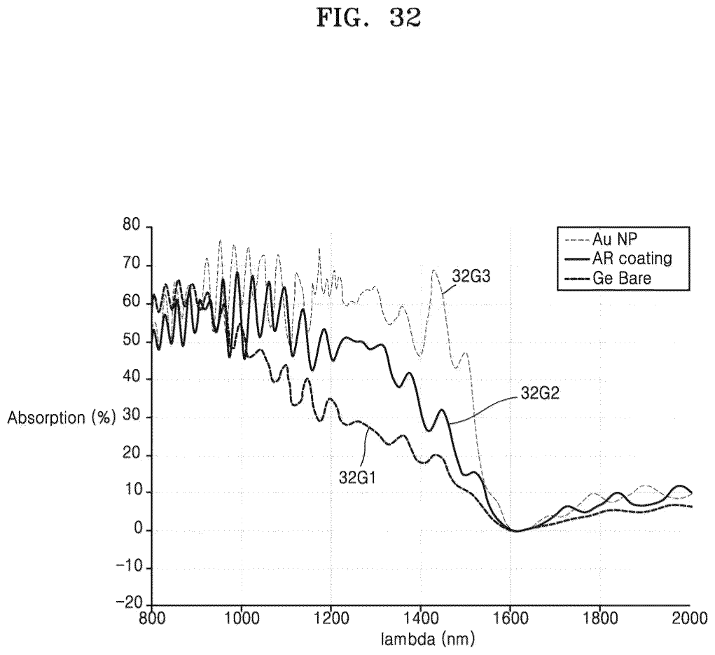

FIG. 32 shows a relationship between a light absorption rate and a wavelength when a thickness of the light absorption layer 136 in each PD sample was lowered from 2 μm to 600 nm in the third simulation.

In FIG. 32, a first graph 32G1 corresponds to the 6th PD sample SP6, a second graph 32G2 corresponds to the 7th PD sample SP7, and third graph 32G3 corresponds to the 9th PD sample SP8.

Comparing the first to third graphs 32G1 to 32G3, when a thickness of the light absorption layer 136 is reduced to 600 nm, the light absorption rate of each of the PD samples SP6, SP7, and SP9 is less than when the thickness of the light absorption layer 136 is 2 μm, but a relative difference in the light absorption rate between the 6th, 7th, and 9th PD samples SP6, SP7, and SP9 may not substantially change.

For example, for incident light with a wavelength of 1310 nm, the light absorption rate of the sixth PD sample SP6 (first graph 32G1) is about 25%, the light absorption rate of the seventh PD sample SP7 (second graph 32G2) is about 49%, and the light absorption rate of the 9th PD sample SP9 (third graph 32G3) is about 61%.

Comparing the first, second, and fourth graphs 30G1, 30G2, and 30G4 of FIG. 30 with the first to third graphs 32G1 to 32G3 of FIG. 32, when a thickness of the light absorption layer 136 is reduced to 600 nm, the light absorption rates of the sixth, seventh, and ninth PD samples SP6, SP7, and SP9 (FIG. 32) are less than the light absorption rates (FIG. 30) when the thickness of the light absorption layer 136 is 2 μm.

However, in the case of the 9th PD sample SP9 in which the nanostructures 142 are provided under the light absorption layer 136, the light absorption rate (third graph 32G3 in FIG. 32) when the thickness of the light absorption layer 136 is 600 nm is equal to or higher than the light absorption rate (first graph 30G1 in FIG. 30) of the sixth PD sample SP6, which does not include the nanostructures 142 and the anti-reflection layer 276 and includes the light absorption layer 136 with a thickness of 2 μm.

These results suggest that it is possible to design an infrared sensor that may maintain or increase the light absorption rate while reducing a dark current, which is noise, by lowering the thickness of the light absorption layer 136.

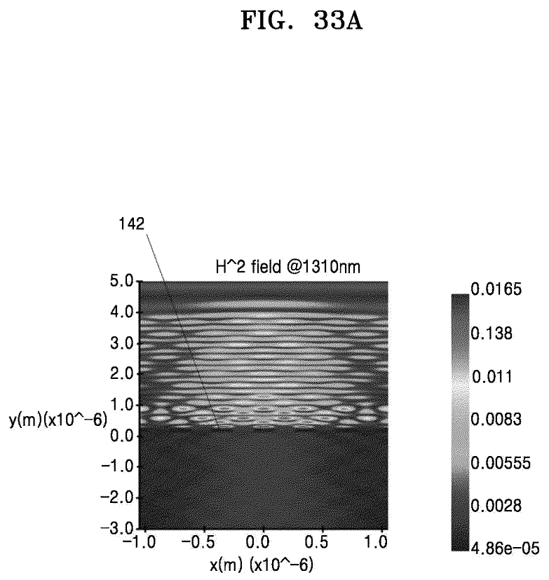

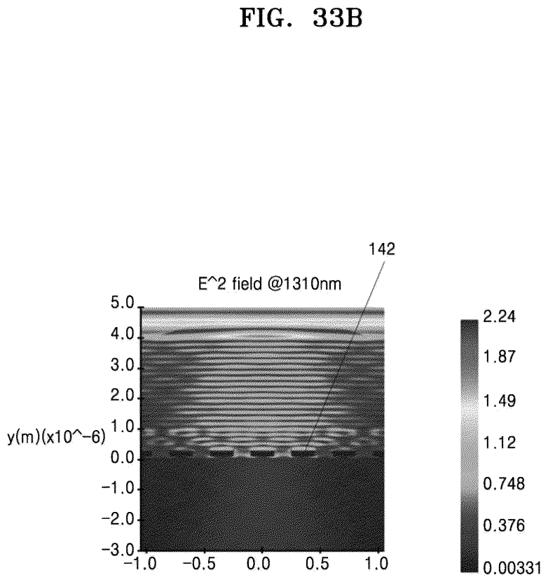

FIGS. 33A and 33B show an energy distribution, that is, an electromagnetic field distribution that appears when infrared rays of 1310 nm are incident on the 9th PD sample SP9 having the same light absorption rate-wavelength relationship as the third graph 32G3 of FIG. 32.

FIG. 33A shows a magnetic field distribution and FIG. 33B shows an electric field distribution.

Referring to FIGS. 33A and 33B, modes of a magnetic field and an electric field are formed in the entire region of the light absorption layer 136 on the nanostructures 142, which suggests that most photons of incident light are trapped in the light absorption layer 136.

These results suggest that, in a back-illuminated PD-type infrared sensor, that is, a BSI type infrared sensor, the nanostructures 142 are provided below the light absorption layer 136 and that being provided close to the light absorption layer 136 is advantageous for increasing the light absorption rate.

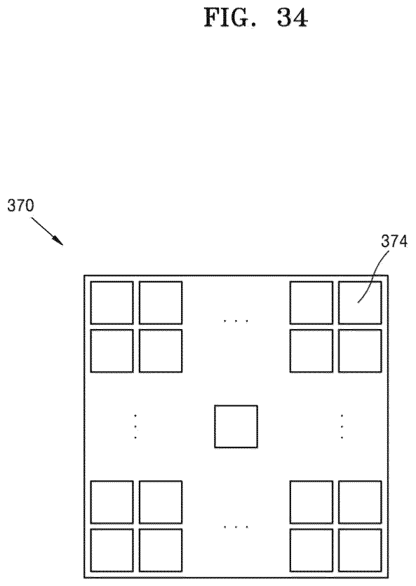

FIG. 34 shows an infrared image sensor 370 according to an example embodiment.

Referring to FIG. 34, the infrared image sensor 370 may include a plurality of pixels 374. The plurality of pixels 374 may form an array. As an example, the plurality of pixels 374 may be arranged at a given pitch in horizontal and vertical directions. In the arrangement of the plurality of pixels 374, a horizontal pitch and a vertical pitch may be the same, but are not limited thereto. Each of the plurality of pixels 374 may be used to sense an infrared image, for example, to sense an infrared image in the SWIR band.

In the infrared image sensor 370, the plurality of pixels 374 may form an array, and each pixel 374 may include an infrared sensor, thus, the infrared image sensor 370 may be expressed as an infrared sensor array.

In the infrared image sensor 370, each pixel 374 may include a PD-type infrared sensor. In one example, each pixel 374 may include an infrared sensor including a configuration corresponding to the PD sample shown in FIG. 22 or an infrared sensor including a configuration corresponding to the ninth PD sample SP9 shown in FIG. 29.

The infrared image sensor 370 of FIG. 34 may be applied to a thermal imaging camera, and a visible light image corresponding to an infrared image may be viewed through the thermal imaging camera.

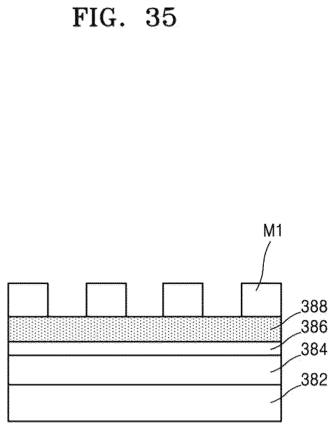

Next, a method of manufacturing a rear-illuminated PD-type infrared sensor will be described with reference to FIGS. 35 to 40.

Referring to FIG. 35, a light absorption layer 384 may be formed on the first substrate 382. In one example, the first substrate 382 may include, but is not limited to, a silicon substrate. In one example, any material that is transparent to infrared light (e.g., SWIR) and may absorb or block visible light may be used as the first substrate 382. In one example, the light absorption layer 384 may be formed by an epitaxy method, but is not limited to this method. In one example, the light absorption layer 384 may be a Ge layer, but is not limited thereto. The light absorption layer 384 may be formed to a thickness of 2 μm or less, for example, 1000 nm or less, 800 nm or less, 600 nm or less, or 500 nm or less, but is not limited thereto. A barrier layer 386 and a material layer 388 for forming nanostructures are sequentially stacked on the light absorption layer 384. In one example, for the formation of the barrier layer 386 and the material layer 388, a commonly used deposition method (e.g., a chemical vapor deposition (CVD), a physical vapor deposition (PVD), sputtering, an atomic layer deposition (ALD) method, etc.) may be used, but is not limited thereto.

The barrier layer 386 may be a material layer that may reduce or prevent a dark current and may include, for example, TiO₂, but is not limited thereto. In one example, the material layer 388 may include a metal, a dielectric material, or a semiconductor material. As an example, the material layer 388 may be a metal layer and may include Au, Ag, or Al, but is not limited thereto. As an example, the material layer 388 may be a semiconductor material layer and may include Si, but is not limited thereto. As an example, the material layer 388 may include a dielectric layer or dielectric material layer and may include TiN, but is not limited thereto.

A photo mask M1 may be formed on the material layer 388. The photo mask M1 may be provided to pattern the material layer 388 into a plurality of nanostructures (e.g., meta-patterns). In one example, the photo mask M1 may include photoresist.

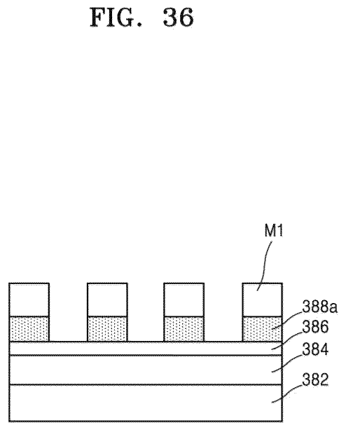

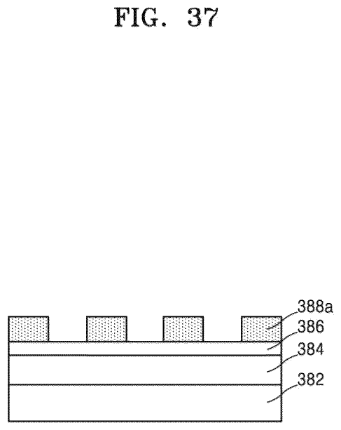

After forming the photo mask M1, as shown in FIG. 36, the material layer 388 around the photo mask M1 may be removed. Dry or wet etching may be used for the removal of the material layer 388. Removal of the material layer 388 may be performed until the barrier layer 386 is exposed. After removing the material layer 388 around the photo mask M1, the photo mask M1 may be removed. In this way, as shown in FIG. 37, a plurality of nanostructures 388a spaced apart from each other may be formed on the barrier layer 386. The plurality of nanostructures 388a may be a plurality of meta-patterns. Accordingly, the plurality of nanostructures 388a formed on the barrier layer 386 may be regarded as a meta surface formed on the barrier layer 386.

The spacing and pitch of the plurality of nanostructures 388a may be determined in a process of forming the photomask M1, and specifications (e.g., height, width, length, etc.) of each nanostructure 388a may also be determined in the process of forming the photomask M1. The specifications of each nanostructure 388a may be less than a wavelength of incident light (e.g., SWIR), for example, may be less than ½ of the wavelength of incident light, but may not be limited thereto.

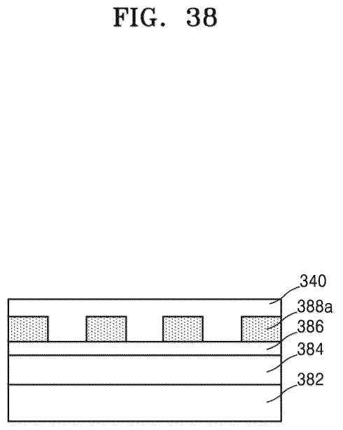

After forming the plurality of nanostructures 388a, as shown in FIG. 38, an upper insulating layer 340 may be formed to cover the plurality of nanostructures 388a. The upper insulating layer 340 may be formed to contact the barrier layer 386 by completely filling the space between the plurality of nanostructures 388a and to entirely cover the plurality of nanostructures 388a. After the upper insulating layer 340 is formed, a planarization process may be performed on an upper surface of the upper insulating layer 340. As a result, the entire upper surface of the upper insulating layer 340 may be flat. In one example, upper insulating layer 340 may be transparent to incident light. In one example, a refractive index of the upper insulating layer 340 may be greater than that of the nanostructure 388a. For example, when the nanostructure 388a includes a metal, the upper insulating layer 340 may include silicon oxide.

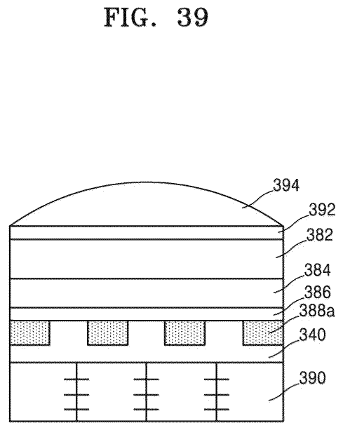

After forming the upper insulating layer 340, as shown in FIG. 39, a resultant product having the upper insulating layer 340 may be turned over. Accordingly, the first substrate 382 may be located above the light absorption layer 384, the plurality of nanostructures 388a may be located below the light absorption layer 384, and the upper insulating layer 340 may be located below the plurality of nanostructures 388a. In this structure, the flat upper surface of the upper insulating layer 340 may become a bottom surface of the upper insulating layer 340.

Referring to FIG. 39, after turning over the resultant product having the upper insulating layer 340, an ROIC layer 390 may be provided to contact the bottom surface of the upper insulating layer 340. In one example, the ROIC layer 390 may be provided such that, after forming separately on another substrate, the ROIC layer 390 may be attached to the bottom surface of the upper insulating layer 340. A micro lens 394 may be formed on the first substrate 382 to collect incident light to the light absorption layer 384. In one example, an anti-reflection layer 392 may be formed between the first substrate 382 and the micro lens 394. The anti-reflection layer 392 may correspond to the anti-reflection layer 276 described with reference to FIG. 27.

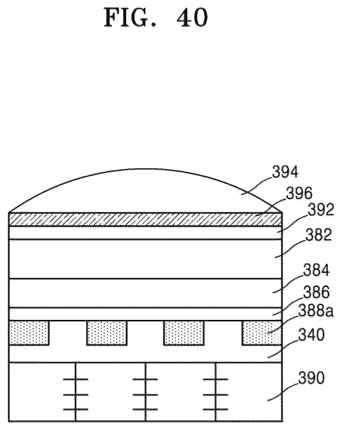

In one example, as shown in FIG. 40, a visible light blocking filter 396 may be formed between the micro lens 394 and the anti-reflection layer 392. The visible light blocking filter 396 may be provided above the micro lens 394 or may be formed between the anti-reflection layer 392 and the first substrate 382.

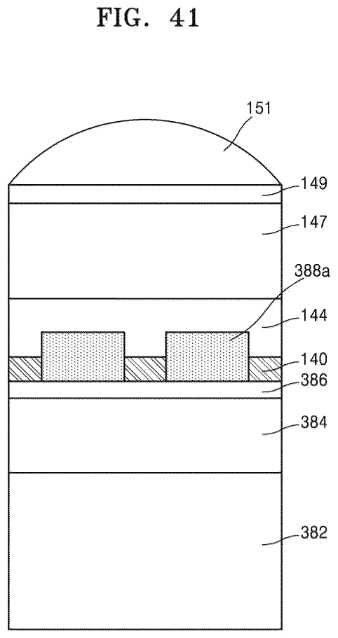

After forming the plurality of nanostructures 388a in FIG. 37, as shown in FIG. 41, the transparent electrode layer 140 may be formed on the barrier layer 386 between the plurality of nanostructures 388a, and then, the upper insulating layer 144 covering the nanostructures 388a and the transparent electrode layer 140 may be formed and an upper surface of the upper insulating layer 144 may be flattened. Next, after forming the ROIC layer 147 on the upper insulating layer 144, the anti-reflection layer 149 and the micro lens 151 may be sequentially formed on the ROIC layer 147. In this way, a forward-illuminated PD-type infrared sensor may be formed. In one example, in FIG. 41, a visible light blocking filter (not shown) may be provided on the micro lens 151, but the visible light blocking filter may also be provided in another location. For example, the visible light blocking filter may be formed between the micro lens 151 and the anti-reflection layer 149, between the anti-reflection layer 149 and the ROIC layer 147, or between the ROIC layer 147 and the upper insulating layer 144.

The short wavelength infrared sensor or infrared image sensor according to an example embodiment described above may be applied to a thermal imaging camera, and may also be used in a device that captures images or photos in limited visibility or low-light conditions.

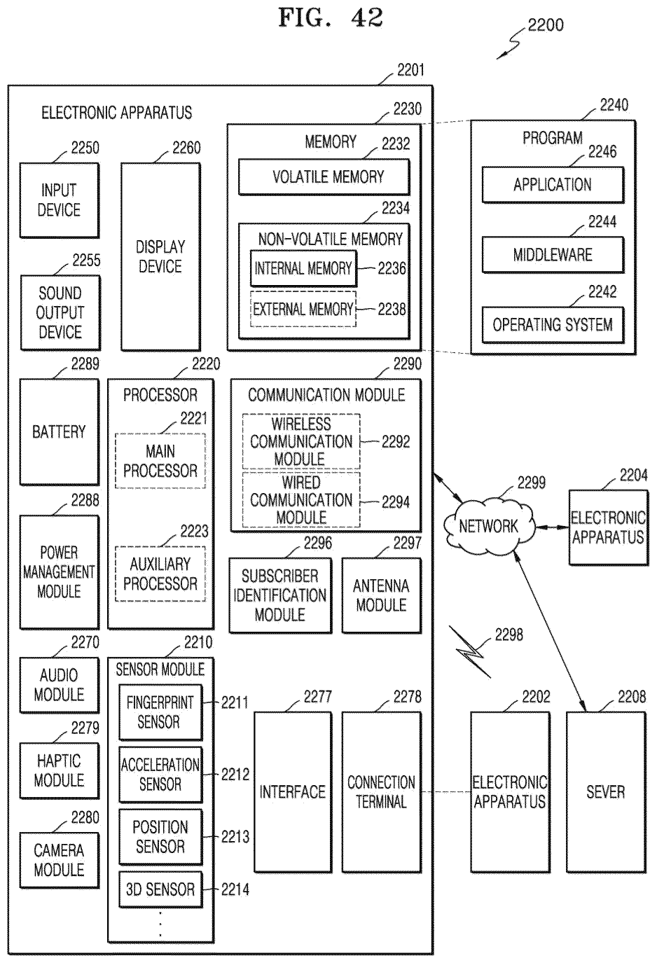

FIG. 42 is a block diagram showing the schematic configuration of an electronic apparatus according to an example embodiment.

Referring to FIG. 42, in a network environment 2200, an electronic apparatus 2201 may communicate with another electronic apparatus 2202 through a first network 2298 (a short-range wireless communication network, etc.) or may communicate with another electronic apparatus 2204 and/or a server 2208 through a second network 2299 (a long distance wireless communication network). The electronic apparatus 2201 may communicate with the electronic apparatus 2204 through the server 2208. The electronic apparatus 2201 may include a processor 2220, a memory 2230, an input device 2250, an audio output device 2255, a display device 2260, an audio module 2270, a sensor module 2210, an interface 2277, a haptic module 2279, a camera module 2280, a power management module 2288, a battery 2289, a communication module 2290, a subscriber identification module 2296, and/or an antenna module 2297. In the electronic apparatus 2201, some of these components (e.g., the display device 2260) may be omitted or other components may be added. Some of these components may be implemented as one integrated circuit. For example, a fingerprint sensor 2211 of the sensor module 2210, an iris sensor, an illuminance sensor, etc. may be implemented in a form embedded in the display device 2260 (e.g., a display, etc.).

The processor 2220 may execute software (e.g., a program 2240, etc.) to control one or a plurality of other components (e.g., hardware, software components, etc.) of the electronic apparatus 2201 connected to the processor 2220 and may perform various data processing or operations. As part of data processing or operations, the processor 2220 may load commands and/or data received from other components (e.g., the sensor module 2210, the communication module 2290, etc.) into a volatile memory 2232, and may process commands and/or data stored in the volatile memory 2232, and store resulting data in a non-volatile memory 2234. The processor 2220 may include a main processor 2221 (e.g., a central processing unit, an application processor, etc.) and an auxiliary processor 2223 (e.g., a graphics processing unit, an image signal processor, a sensor hub processor, a communication processor, etc.) that may be operated independently or together with the main processor 2221. The auxiliary processor 2223 may use less power than the main processor 2221 and may perform a specialized function.

The auxiliary processor 2223 may control functions and/or states related to some of the components (e.g., the display device 2260, the sensor module 2210, the communication module 2290) of the electronic apparatus 2201 instead of the main processor 2221 while the main processor 2221 is in an inactive state (e.g., sleep state), or together with the main processor 2221 while the main processor 2221 is in an active state (e.g., application execution state). The auxiliary processor 2223 (e.g., an image signal processor, a communication processor, etc.) may be implemented as a part of other functionally related components (e.g., the camera module 2280, the communication module 2290, etc.).

The memory 2230 may store various data required by components of the electronic apparatus 2201 (e.g., the processor 2220, the sensor module 2276, etc.). The data may include, for example, input data and/or output data for software (such as the program 2240) and instructions related to the command. The memory 2230 may include a volatile memory 2232 and/or a non-volatile memory 2234. The non-volatile memory 2234 may include an internal memory 2236 and an external memory 2238. The program 2240 may be stored as software in the memory 2230, and may include an operating system 2242, middleware 2244, and/or an application 2246.

The input device 2250 may receive commands and/or data to be used in a component (e.g., the processor 2220) of the electronic apparatus 2201 from the outside of the electronic apparatus 2201 (e.g., a user). The input device 2250 may include a microphone, a mouse, a keyboard, and/or a digital pen (such as a stylus pen).

The sound output device 2255 may output a sound signal to the outside of the electronic apparatus 2201. The sound output device 2255 may include a speaker and/or a receiver. The speaker may be used for general purposes, such as multimedia playback or recording playback, and the receiver may be used to receive incoming calls. The receiver may be integrated as a part of the speaker or may be implemented as an independent separate device.

The display device 2260 may visually provide information to the outside of the electronic apparatus 2201. The display device 2260 may include a control circuit for controlling a display, a hologram device, or a projector and a corresponding device. The display device 2260 may include a touch circuitry configured to sense a touch, and/or a sensor circuitry configured to measure the intensity of force generated by the touch (e.g., a pressure sensor, etc.).

The audio module 2270 may convert a sound into an electric signal or, conversely, convert an electric signal into a sound. The audio module 2270 may obtain a sound through the input device 2250 or may output a sound through a speaker and/or headphone of the sound output device 2255 and/or another electronic apparatus (e.g., the electronic apparatus 2202) directly or wirelessly connected to electronic apparatus 2201.

The sensor module 2210 may detect an operating state (e.g., power, temperature, etc.) of the electronic apparatus 2201 or an external environmental state (e.g., user state, etc.), and may generate an electrical signal and/or data value corresponding to the sensed state. The sensor module 2210 may include a fingerprint sensor 2211, an acceleration sensor 2212, a position sensor 2213, a 3D sensor 2214, and the like, and in addition to the above sensors, may include an iris sensor, a gyro sensor, a barometric pressure sensor, a magnetic sensor, a grip sensor, a proximity sensor, a color sensor, an infrared (IR) sensor, a biometric sensor, a temperature sensor, a humidity sensor, and/or an illuminance sensor.

The 3D sensor 2214 may sense a shape and movement of an object by irradiating a predetermined light to the object and analyzing light reflected from the object, and may include a meta-optical device.

The interface 2277 may support one or more designated protocols that may be used by the electronic apparatus 2201 to connect directly or wirelessly with another electronic apparatus (e.g., the electronic apparatus 2102). The interface 2277 may include a High Definition Multimedia Interface (HDMI), a Universal Serial Bus (USB) interface, an SD card interface, and/or an audio interface.

The connection terminal 2278 may include a connector through which the electronic apparatus 2201 may be physically connected to another electronic apparatus (e.g., the electronic apparatus 2202). The connection terminal 2278 may include an HDMI connector, a USB connector, an SD card connector, and/or an audio connector (e.g., a headphone connector).

The haptic module 2279 may convert an electrical signal into a mechanical stimulus (e.g., vibration, movement, etc.) or an electrical stimulus that the user may perceive through tactile or kinesthetic sense. The haptic module 2279 may include a motor, a piezoelectric element, and/or an electrical stimulation device.

The camera module 2280 may capture still images and moving images. The camera module 2280 may include a lens assembly including one or more lenses, image sensors, image signal processors, and/or flashes. The lens assembly included in the camera module 2280 may collect light emitted from an object, which is an imaging target. In one example, the camera module 2280 may be configured to capture at least one of a visible light image and an infrared image of the object. In one example, the camera module 2280 may include a short wavelength infrared sensor or an infrared image sensor (e.g., 370 in FIG. 34) provided with a nanostructure (meta-pattern) on or below the light absorption layer according to an example embodiment described above to capture an infrared image of the object. In one example, the image signal processor included in the camera module 2280 may perform converting the captured infrared image into a visible light image and also overlapping the captured infrared image on the visible light image.

The power management module 2288 may manage power supplied to the electronic apparatus 2201. The power management module 2288 may be implemented as part of a Power Management Integrated Circuit (PMIC).

The battery 2289 may supply power to components of the electronic apparatus 2201. The battery 2289 may include a non-rechargeable primary cell, a rechargeable secondary cell, and/or a fuel cell.

The communication module 2290 may establish a direct (e.g., wired) communication channel and/or wireless communication channel between the electronic apparatus 2201 and other electronic apparatuses (e.g., the electronic apparatus 2202, an electronic apparatus 2204, server 2208, etc.) and may support the performance of communication through the established communication channels. The communication module 2290 may include one or more communication processors that operate independently of the processor 2220 (e.g., an application processor) and support direct communication and/or wireless communication. The communication module 2290 may include a wireless communication module 2292 (e.g., a cellular communication module, a short-range wireless communication module, a Global Navigation Satellite System (e.g., GNSS, etc.) communication module) and/or a wired communication module 2294 (e.g., a Local Area Network (LAN) communication module, or a power line communication module, etc.). Among these communication modules, a corresponding communication module may communicate with other electronic apparatuses through the first network 2298 (e.g., a short-range communication network, such as Bluetooth, WiFi Direct, or Infrared Data Association (IrDA)) or the second network 2299 (a telecommunication network, such as a cellular network, the Internet, or a computer network (LAN) and WAN, etc.). The various types of communication modules may be integrated into one component (e.g., a single chip, etc.) or implemented as a plurality of components (e.g., plural chips) separate from each other. The wireless communication module 2292 may identify and authenticate the electronic apparatus 2201 within a communication network, such as the first network 2298 and/or the second network 2299 by using subscriber information (such as, International Mobile Subscriber Identifier (IMSI)) stored in a subscriber identification module 2296.

The antenna module 2297 may transmit or receive signals and/or power to and from the outside (e.g., other electronic apparatuses, etc.). The antenna may include a radiator having a conductive pattern formed on a substrate (e.g., PCB, etc.). The antenna module 2297 may include one or a plurality of antennas. When a plurality of antennas is included in the antenna module 2297, an antenna suitable for a communication method used in a communication network, such as the first network 2298 and/or the second network 2299 from among the plurality of antennas may be selected by the communication module 2290. Signals and/or power may be transmitted or received between the communication module 2290 and another electronic apparatus through the selected antenna. In addition to the antenna, other components (e.g., an RFIC, etc.) may be included as a part of the antenna module 2297.

Some of the components are connected to each other through a communication method between peripheral devices (e.g., a bus, a General Purpose Input and Output (GPIO), a Serial Peripheral Interface (SPI), a Mobile Industry Processor Interface (MIPI), etc.), and may interchange signals (e.g., commands, data, etc.).

The command or data may be transmitted or received between the electronic apparatus 2201 and the external electronic apparatus 2204 through the server 2208 connected to the second network 2299. The other electronic apparatuses 2202 and 2204 may be the same or different types of electronic apparatus 2201. All or some of operations performed in the electronic apparatus 2201 may be performed in one or more of the other electronic apparatuses 2202, 2204, and 2208. For example, when the electronic apparatus 2201 needs to perform a function or service, the electronic apparatus 2201 may request one or more other electronic apparatuses to perform part or all function or service instead of executing the function or service itself. One or more other electronic apparatuses receiving the request may execute an additional function or service related to the request, and transmit a result of the execution to the electronic apparatus 2201. For this purpose, cloud computing, distributed computing, and/or client-server computing technologies may be used.

The short wavelength infrared sensor according to an example embodiment may be provided with a plurality of nanostructures on one side of a light absorption layer (e.g., Ge layer) that absorbs infrared rays (e.g., SWIR) as a light absorption enhancement layer to enhance the light absorption rate of the light absorption layer. The plurality of nanostructures may be provided close to the light absorption layer to the extent that a plasmonic amplification effect occurs. As the plurality of nanostructures are provided, the light absorption rate of the light absorption layer may be increased than when the plurality of nanostructures are not provided.

Therefore, when the short wavelength infrared sensor according to an example embodiment is used, a thickness of the light absorption layer may be reduced less than that of an existing infrared sensor, while maintaining the light absorption rate equal to or greater than that of the existing infrared sensor.

Considering that a dark current increases in proportional to the thickness of the light absorption layer, when the short wavelength infrared sensor according to an example embodiment is used, the thickness of the light absorption layer may be formed to be thin, so the dark current may be reduced and the light absorption rate may be increased compared to the existing infrared sensor.

Additionally, in the short wavelength infrared sensor according to an example embodiment, a width of the light absorption layer may be reduced compared to the existing light absorption layer while maintaining the light absorption rate equal to or greater than the existing infrared sensor due to the effect of increasing the light absorption rate by the nanostructures. Accordingly, the operating speed of the short wavelength infrared sensor according to an example embodiment may be increased.

While many matters have been described in detail in the above description, they should be construed as illustrative of example embodiments rather than to limit the scope of the invention. Therefore, the scope of the present inventive concept should not be defined by the embodiments described above, but should be determined by the technical spirit described in the claims.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A short wavelength infrared sensor comprising:
a substrate layer;
a light absorption layer provided on the substrate layer and having a higher absorption rate for a short wavelength infrared light than an absorption rate for a visible light;
a light absorption enhancement layer provided on the light absorption layer to enhance a light absorption rate of the light absorption layer, the light absorption enhancement layer including a plurality of nanostructures; and
an upper insulating layer covering the plurality of nanostructures and having a refractive index greater than a refractive index of each of the plurality of nanostructures,
wherein the light absorption layer comprises germanium (Ge).

2. The short wavelength infrared sensor of claim 1, wherein the substrate layer comprises a channel layer, and the channel layer is in contact with the light absorption layer.

3. The short wavelength infrared sensor of claim 2, wherein the substrate layer comprises a p-type substrate, an n+ back gate substrate, and a gate insulating layer,
wherein the light absorption layer faces the n+ back gate substrate with the channel layer therebetween, and the plurality of nanostructures are in contact with the light absorption layer, and
the short wavelength infrared sensor further comprises a first electrode layer and a second electrode layer, the first electrode layer and the second electrode layer being separated from the light absorption layer, being in contact with the channel layer, and being spaced apart from each other.

4. The short wavelength infrared sensor of claim 3, further comprising:
a first contact prevention layer that prevents a contact between the light absorption layer and the first electrode layer; and
a second contact prevention layer that prevents a contact between the light absorption layer and the second electrode layer.

5. The short wavelength infrared sensor of claim 1, wherein the light absorption layer is provided in a straight-line shape or a curved shape.

6. The short wavelength infrared sensor of claim 5, wherein the plurality of nanostructures comprise a metal meta-pattern or a meta-pattern of a dielectric material.

7. The short wavelength infrared sensor of claim 4, wherein the light absorption layer comprises a first light absorption layer and a second light absorption layer spaced apart from each other between the first contact prevention layer and the second contact prevention layer, and
wherein, among the plurality of nanostructures, nanostructures provided on the first light absorption layer and nanostructures provided on the second light absorption layer are provided to be perpendicular to each other.

8. The short wavelength infrared sensor of claim 1, wherein, among the plurality of nanostructures, a plurality of first nanostructures are aligned to correspond to a first polarization component of incident light, and a plurality of second nanostructures are aligned to correspond to a second polarization component of the incident light.

9. The short wavelength infrared sensor of claim 1, wherein the plurality of nanostructures are aligned at a first pitch in a first section of the light absorption layer, and are aligned at a second pitch different from the first pitch in a second section of the light absorption layer, the second section being different from the first section.

10. The short wavelength infrared sensor of claim 1, wherein the light absorption enhancement layer is provided between the light absorption layer and the substrate layer, and
wherein the short wavelength infrared sensor further comprises a barrier layer provided between the light absorption layer and the light absorption enhancement layer.

11. The short wavelength infrared sensor of claim 10, wherein both the light absorption enhancement layer and the barrier layer are disposed on or below the light absorption layer, or disposed on or above the light absorption layer.

12. The short wavelength infrared sensor of claim 11, wherein both the light absorption enhancement layer and the barrier layer are disposed on the light absorption layer, and a transparent electrode layer provided around the plurality of nanostructures is included on the barrier layer, and
wherein a height of the transparent electrode layer is less than that of each of the plurality of nanostructures.

13. The short wavelength infrared sensor of claim 1, wherein the light absorption enhancement layer is provided between the light absorption layer and the substrate layer, and the plurality of nanostructures are in contact with the light absorption layer.

14. The short wavelength infrared sensor of claim 10, further comprising an anti-reflection film, a visible light blocking filter, and a micro lens provided on the light absorption layer,
wherein the light absorption enhancement layer and the barrier layer are both provided below the anti-reflection film, the visible light blocking filter, and the micro lens, and
wherein the short wavelength infrared sensor further comprises a readout circuit layer provided above or below the light absorption layer.

15. An electronic apparatus comprising the short wavelength infrared sensor of claim 1.

16. A method of manufacturing a short wavelength infrared sensor, the method comprising:
forming a light absorption layer having a higher absorption rate for a short wavelength infrared light than an absorption rate for a visible light, on a substrate layer;
forming a plurality of metal nanostructures on the light absorption layer to enhance a light absorption rate of the light absorption layer; and
forming an insulating layer covering the plurality of metal nanostructures,
wherein the light absorption layer comprises germanium (Ge), and
wherein the insulating layer has a refractive index greater than a refractive index of each of the plurality of metal nanostructures.

17. The method of claim 16, further comprising forming a barrier layer between the light absorption layer and the plurality of metal nanostructures.

18. The method of claim 17, further comprising forming a transparent electrode layer around the plurality of metal nanostructures on the barrier layer.

19. The method of claim 16, further comprising forming an anti-reflection layer, a visible light blocking filter, and a micro lens on the light absorption layer.

20. The method of claim 16, wherein the plurality of metal nanostructures comprise a first metal nanostructure corresponding to a first polarization component of incident light and a second metal nanostructure corresponding to a second polarization component of the incident light.
